(19) United States
(12) Patent Application Publication
(10) Pub. No.: US 2013/0037843 A1
(43) Pub. Date: Feb. 14, 2013

(54) LIGHT EMITTING TRANSISTOR

(71) Applicants: Takeshi Yamao, Kyoto-shi (JP); Shu Hotta, Kyoto-shi (JP); Yoichi Sakurai, Kyoto-shi (JP); Yoshitaka Makino, Kyoto-shi (JP); Kohei Terasaki, Kyoto-shi (JP); Akinori Okada, Kyoto-shi (JP)

(72) Inventors: Takeshi Yamao, Kyoto-shi (JP); Shu Hotta, Kyoto-shi (JP); Yoichi Sakurai, Kyoto-shi (JP); Yoshitaka Makino, Kyoto-shi (JP); Kohei Terasaki, Kyoto-shi (JP); Akinori Okada, Kyoto-shi (JP)

(21) Appl. No.: 13/578,365

(22) PCT Filed: Feb. 9, 2011
(86) PCT No.: PCT/JP2011/052760

§ 371 Date: Oct. 24, 2012

(30) Foreign Application Priority Data
Feb. 12, 2010 (JP) 2010-028600

(51) Int. Cl. H01L 33/58; H01L 33/62

(52) U.S. Cl. 257/98; 257/99; 257/E33.062; 257/E33.06

(57) ABSTRACT

A light emitting transistor of the present invention has a light emitting layer, both a source electrode and a drain electrode both of which are connected with the light emitting layer electrically, an insulation layer arranged on the light emitting layer, a gate electrode arranged on the insulation layer. The light emitting layer is made from an organic semiconductor material. The light emitting transistor has also a periodic structure and the gate electrode to which an AC voltage is applied. And the emission intensity can be high, and width of the emission spectrum can be reduced. In addition, it is easy to control the amplitude of the emitting light and the width of emission spectrum reproducibly.

### TECHNICAL FIELD

The present invention relates to a light emitting transistor, a process for manufacturing the light emitting transistor, and a method for emitting a light of which intensity is amplified and/or of which width of the light emission spectrum is narrowed. In concrete terms, the present invention relates to a light emitting transistor comprising a light emitting layer made from an organic semiconductor material, wherein a periodic structure is formed and an AC voltage is applied to a gate electrode, a process for manufacturing the same, and a method for emitting light of which intensity is amplified and/or of which the width of the light emission spectrum is narrowed.

### BACKGROUND ART

An organic light emitting field-effect transistor (OLEFET) is known as a light emitting device of three terminals that is made from the organic semiconductor material.

Non-Patent Document 1 discloses that the device which is composed of the OLEFET and the diffraction grating having convex parts of 2-3 μm width and 30 nm height. The diffraction grating is constructed by the ditch and the convex part made from tantalum pentoxide (Ta₂O₅) in the vertical direction on the glass plate used as a substrate. Two gold electrodes are arranged with the interval of 10 μm, and used as the source electrode and the drain electrode. The amorphous film of poly (9,9-dioctylfluorene-alt-benzothiadiazole, in which both electrons and holes flow, is arranged as an organic semiconductor layer on the gold electrode and the diffraction grating formed by spin-coating method. The gate insulation layer is arranged on the organic semiconductor layer using Polymethyl-methacrylate. The gate electrode is arranged on the gate insulation layer using gold or silver.

Non-Patent Document 1 discloses that the emission spectrum becomes sharper from the device with the diffraction grating compared with the device without the diffraction grating when the electric voltage applying to the source electrode, the drain electrode and the gate electrode. However, it is uncertain whether this difference is linewidth reduction or not. If it is linewidth reduction, the level of linewidth reduction is insufficient. In addition, the reproducibility is also uncertain.

Non-Patent Document 1 discloses also that in the device that has the diffraction grating, the symptom of the laser oscillation is not shown even if it excites it electrically. Non-Patent Document 1 discloses also that the density of the generated exciton is about four digits lower than the density of the exciton demanded from the laser oscillation threshold.

Patent Document 1 discloses that an organic light emitting device having a tabular crystal of an organic semiconductor material and a diffraction grating emits light when the light of the low energy such as the mercury lamps is irradiated, and the light amplifies and is made a light emission line-narrowing spectrum. However, Patent Document 1 discloses the light emission line-narrowing spectrum by optical excitation, not by electrical excitation.

Patent Document 2 discloses that an organic light emitting field-effect transistor has a light emitting layer made from organic semiconductor material, a source electrode and a drain electrode connected with a light emitting layer electrically, and a gate electrode connected with the light emitting layer through a insulator layer, and the transistor can improve intensity of emitting light from the light emitting layer by applying AC voltage to the gate electrode, the drive circuit of the organic field-effect transistor can be facilitated.

However, Patent Document 2 doesn't discloses any reproducibility (or, any reliability) of the strength of emitting light and the light emission line-narrowing spectrum.

### Citation List

### Patent Document 1: JP 2010-15874A

### Patent Document 2: WO 2009/099205A1

Non-Patent Document 1: M. C. Gwinner, S. Khodabakhsh, M. H. Song, H. Schweizer, H. Giessen and H. Sirringhaus, Adv. Funct. Mater., 19 (2009) 1360-1370.

### SUMMARY OF THE INVENTION

### Technical Problem

The method of obtaining a light of which the width of the emission spectrum is narrowed from OLEFETs is academically and practically interesting, however, it is hardly reported about them. In past OLEFETs, strength of an emitting light, narrowness of width of the emission light spectrum, reproducibility thereof and stability of the OLEFETs are not enough. In addition, it is not easy to control the amplitude of the emitting light and the width of the emission light spectrum reproducibly.

### Solution to the Problem

After intensive research to solve the above-mentioned problems, the present inventors have found that a light emitting transistor comprising a light emitting layer made from an organic semiconductor material and a periodic structure, in which an AC voltage is applied to a gate electrode, can solve the above-mentioned problems surprisingly, and have completed the present invention.

That is, in an aspect, the present invention provides a light emitting transistor comprising: a light emitting layer; a source electrode electrically connected with the light emitting layer; a drain electrode electrically connected with the light emitting layer; and a gate electrode connected with the light emitting layer through a medium of an insulation layer, wherein

the light emitting layer is formed from an organic semiconductor material, the light emitting transistor has a periodic structure, and an AC voltage is applied to the gate electrode.

In an embodiment according to the present invention, the light emitting transistor in which the light emitting layer includes a tabular (or slab) crystal of the organic semiconductor material is provided.

In another embodiment according to the present invention, the light emitting transistor in which the periodic structure is at least one kind selected from a group consisting of a one-dimensional diffraction grating, a two-dimensional diffraction grating, a photonic crystal and a multilayer film is provided.

In a preferable embodiment according to the present invention, the light emitting transistor in which the periodic structure is arranged on the light emitting layer or the insulation layer is provided.

### Effects of Invention

A light emitting transistor according to the present invention comprises: a light emitting layer; a source electrode electrically connected with the light emitting layer; a drain electrode electrically connected with the light emitting layer; and a gate electrode connected with the light emitting layer through a medium of an insulation layer, and wherein the light emitting layer is formed from an organic semiconductor material, the light emitting transistor has a periodic structure, and an AC voltage is applied to the gate electrode.

Therefore, the light emitting transistor is excellent in amplification of the intensity of the emitting light, narrowness of the width of the emission light spectrum, reproducibility thereof and stability of the device, and further, it is easy to control the amplitude of the intensity of the emitting light and the narrowness of the width of the emission light spectrum reproducibly.

When the light emitting layer is made from an organic semiconductor material including a tabular (or slab) crystal, since the tabular crystal may have the anisotropy of light emission and the electric conduction, the emission is selectively caused in a specific direction (more concretely, a direction parallel to the principal plane of the tabular crystal), and is not caused in a useless direction (more concretely, a direction perpendicular to the principal surface of the tabular crystal). So the emission is efficient.

When the periodic structure is at least one kind selected from a group consisting of a one-dimensional diffraction grating, a two-dimensional diffraction grating, a photonic crystal and a multilayer film, a light of a specific wavelength in the spectrum caused by the emission can be selectively sharpened.

When the periodic structure is arranged on the light emitting layer or the insulation layer, a light of a specific wavelength in the spectrum caused by the emission can be selectively further sharpened.

### BRIEF DESCRIPTION OF THE DRAWINGS

FIG. 1 is a schematic view showing a light emitting transistor according to a first embodiment of the present invention.

FIG. 1a is a cross sectional view from the horizontal direction showing a light emitting transistor according to a first embodiment.

FIG. 1b is a cross sectional view from front direction showing a light emitting transistor according to a first embodiment.

FIG. 2 is a photomicrograph showing a light emitting transistor according to a first embodiment.

FIG. 2a is a pattern diagram of a photomicrograph showing a light emitting transistor according to a first embodiment.

FIG. 3 is a perspective view showing a diffraction grating.

FIG. 4 is a three-dimensional view showing a part of a diffraction grating on the silicon dioxide film observed with atomic force microscope (AFM).

FIG. 5 is a cross sectional view showing a vertical cross section in lattice direction of a diffraction grating observed with AFM according to FIG. 4.

FIG. 6 is a schematic view showing a sublimation and recrystallization equipment of organic semiconductor material.

FIG. 6b is a schematic view showing a test tube 21 in which organic semiconductor material is sublime and is made recrystallization.

FIG. 7 is a block diagram showing a driving circuit that the light emitting transistor emits light by the current excitation.

FIG. 8 is a characteristic figure showing a light emitting spectra of an organic light emitting device observed when DC voltages are applied to a source electrode and a drain electrode and AC voltage of rectangular wave is applied to a gate electrode according to a first embodiment.

Applying voltage conditions corresponding to those from A to E are shown in TABLE 1.

FIG. 9 is a characteristic figure showing peak intensities of light emitting spectra as a function of input electric power observed when DC voltages are applied to a source electrode and a drain electrode and AC voltage of rectangular wave is applied to a gate electrode according to a first embodiment.

FIG. 10 is a cross sectional view showing a light emitting transistor according to a first comparison example.

FIG. 11 is a schematic view showing a interdigitated array electrode used for a light emitting transistor according to a first comparison example.

FIG. 12 is a photomicrograph showing a light emitting transistor according to a first comparison example.

FIG. 13 is a characteristic figure showing light emitting spectrum of an organic light emitting device observed when DC voltage is applied to a source electrode and a drain electrode and AC voltage of rectangular wave is applied to a gate electrode according to a first comparison example.

FIG. 14 is a cross sectional view showing a light emitting transistor according to a second embodiment.

FIG. 15 is a photomicrograph showing a light emitting transistor before metallic electrodes are formed according to a second embodiment.

FIG. 16 is a photomicrograph showing a light emitting transistor to a second embodiment.

FIG. 17 is a characteristic figure showing light emitting spectra of an organic light emitting device observed when DC voltage is applied to a source electrode and a drain electrode and AC voltage of rectangular wave is applied to a gate electrode according to a second embodiment. Applying voltage conditions corresponding to those from A to C are shown in TABLE 2.

FIG. 18 is a cross sectional view showing a light emitting transistor according to a third embodiment.

FIG. 19 is a photomicrograph showing a light emitting transistor to a third embodiment.

FIG. 20 is a characteristic figure showing light emitting spectra of a organic light emitting device observed when DC voltage is applied to a source electrode and a drain electrode and AC voltage of rectangular wave is applied to a gate electrode according to a third embodiment. Applying voltage conditions corresponding those from A to B are shown in TABLE 3.

FIG. 21 is a cross sectional view showing a light emitting transistor according to a fourth embodiment.

FIG. 22 is a photomicrograph showing a light emitting transistor to a fourth embodiment.

FIG. 23 is a characteristic figure showing light emitting spectra of a organic light emitting device observed when DC voltage is applied to a source electrode and a drain electrode and AC voltage of sine wave is applied to a gate electrode according to a fourth embodiment. Applying voltage conditions corresponding to those from A to D are shown in TABLE 4.

FIG. 24 is a cross sectional view showing a light emitting transistor according to a fifth embodiment.

FIG. 25 is a two-dimensional view observed by AFM showing a part of a two-dimensional periodic structure 13a formed to a resist layer 17a.

FIG. 26 is a photomicrograph taken from normal direction on the substrate showing an AC5 crystal 11a and an AC5-CF₃ crystal 11b formed on silicon substrate 12.

FIG. 27 is a photomicrograph showing a light emitting transistor to a fifth embodiment.

FIG. 28 is a characteristic figure showing light emitting spectra of an organic light emitting device observed when DC voltage is applied to a source electrode and a drain electrode and AC voltage of sine or rectangular wave is applied to a gate electrode according to a fifth embodiment. Applying voltage conditions corresponding to those from A to E are shown in TABLE 5.

### DESCRIPTION OF REFERENCE NUMERALS

10 Light Emitting Transistor

11 Organic Semiconductor Crystal

11a Organic Semiconductor Crystal

11b Organic Semiconductor Crystal

12 Silicon Substrate with Dioxide Film

13 Diffraction Grating

13a 2-Dimentional Periodic Structure

14 Electrode

14a Chromium Layer

14b Gold Layer

14c Magnesium-Silver Alloy Layer

14d Silver Layer

14n Source Electrode

14p Drain Electrode

15 Silicon Dioxide Layer

16 Silicon Layer

17 Photoresist Layer

17a Resist Layer

18 Amorphous Organic Semiconductor Film

19 Gold Electrode

20 Sublimation Recrystallization Equipment

21 Test Tube

22 Rubber Ring

23 Glass Ring

23a-d Glass Ring

24 Organic Semiconductor Material Powder

25 Glass Tube

26 Nitrogen Gas

27 Source Heater

28 Growth Heater

29 Organic Semiconductor Crystals

31 Nitrogen Gas Cylinder

32 Flow Meter

33 Cold Trap

34 Bubbler

40 Driving Circuit

41 DC Power Supply

42 DC Power Supply

43 AC Power Supply

60 Light Emitting Transistor

### DETAILED DESCRIPTION OF THE INVENTION

A light emitting transistor of the present invention has a light emitting layer made from an organic semiconductor material, a periodic structure and a gate electrode to which an AC voltage is applied.

It is desirable that the light emitting transistor of the present invention is an organic light emitting field-effect transistor (OLEFET) known as an emission device of three terminals generally. The transistor of the present invention has a light emitting layer made from an organic semiconductor material, a source electrode and a drain electrode electrically connected with the light emitting layer, and a gate electrode connected with the light emitting layer through a medium of an insulation layer.

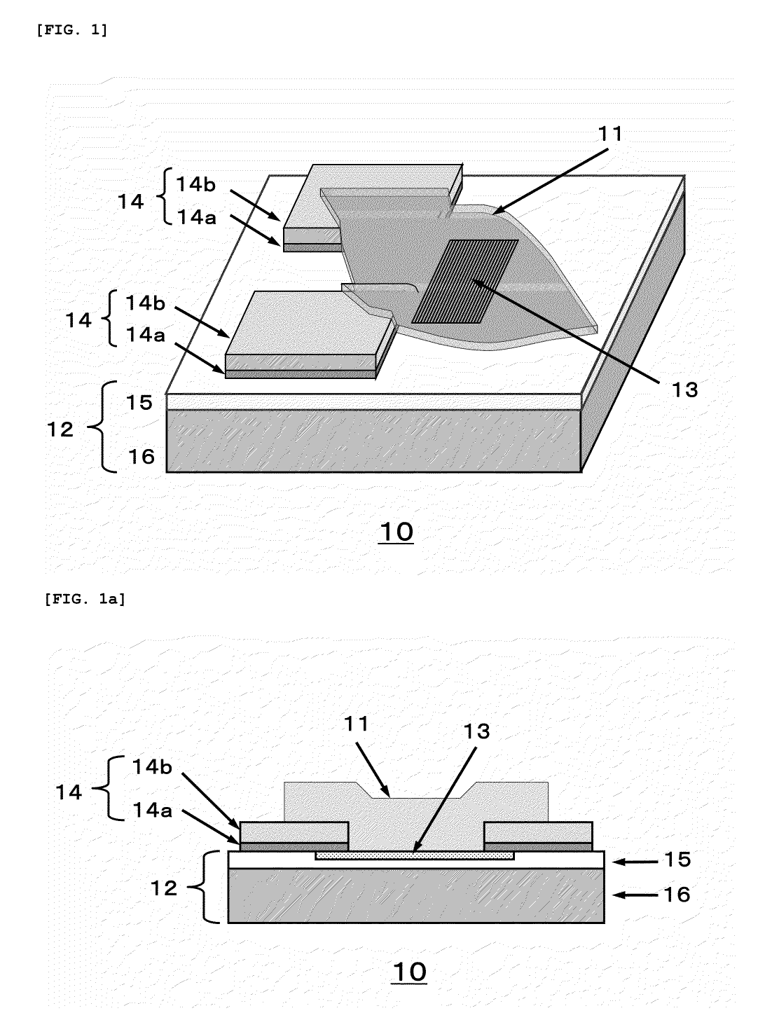

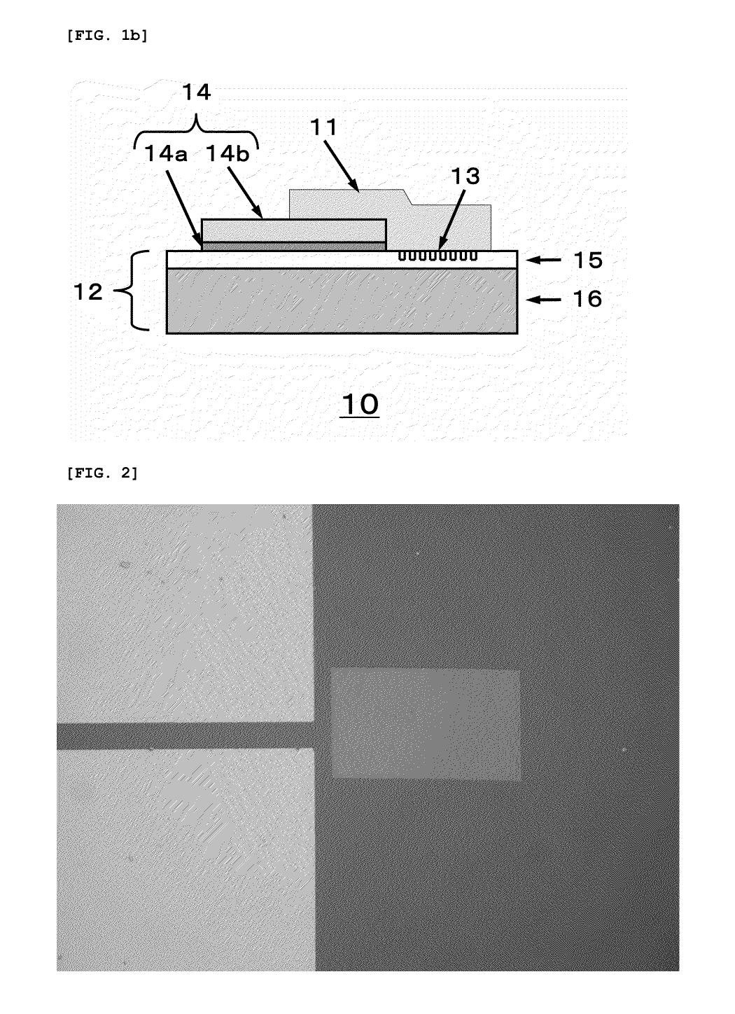

The light emitting transistor according to the present invention is exemplified with reference to appended FIG. 1, in which transistor the light emitting layer includes a tabular crystal of the organic semiconductor material and the periodic structure is a diffraction grating. The light emitting transistor has a light emitting layer made from a tabular crystal of the organic semiconductor material, a source electrode, a drain electrode, a gate insulation layer and a gate electrode, and further a diffraction grating.

When the light emitting layer includes the tabular crystal of the organic semiconductor material and the periodic structure is a diffraction grating, the light emitting transistor of the present invention is more preferable since it can emit a light easily, amplify the emitted light and narrow the width of the emitted light spectrum by applying an AC voltage to the gate electrode.

In the present invention, “light emitting layer” means a layer which emits light by applying an electric field, and is made from an organic semiconductor material. And the light emitting layer is not particularly limited as long as the objective light emitting transistor of the present invention can be obtained.

In the present invention, “organic semiconductor material” means a material which is generally called organic semiconductor material. The organic semiconductor material is not particularly limited as long as the objective light emitting transistor of the present invention can be obtained. The form of the organic semiconductor material is not particularly limited as long as the objective light emitting transistor of the present patent can be obtained. Because the light emitting layer is made from the organic semiconductor material, it may become a planar stratified form generally. For instance, a tabular crystal, an epitaxial growth crystal, an amorphous film, and a decentralized film of the organic semiconductor material etc. can be exemplified. And it is preferred that a tabular crystal is used as the light emitting layer.

As such organic semiconductor materials, the compounds shown in Eq. (I) are exemplified.

(X)ₘ−(Y)ₙ Eq. (I)

[Here, each X is a six-membered ring available to be modified independently with hetero atoms (such as nitrogen, sulfur, oxygen, selenium, and tellurium), substituent groups [such as alkyl groups (e.g. methyl groups, ethyl groups, propyl groups, butyl groups, pentyl groups, hexyl groups, heptyl groups, and octyl groups), halogen, alkoxyl groups (e.g. methoxy groups and ethoxy groups), alkenyl groups, cyano groups, and fluorinated alkyl groups (e.g. trifluoromethyl groups)]. It is preferable that each X is a benzene ring, a pyridine ring, a pyridazine ring, p-pyridyl vinylene, pyran, and a thiopyran ring. It is more preferable that each X is a benzene ring.
The number m is 0 to 20 preferably, and is 1 to 8 more preferably.
Each Y is a five-membered ring available to be independently modified with hetero atoms (such as nitrogen, sulfur, oxygen, selenium, and tellurium), substituent groups [such as alkyl groups (e.g. methyl groups, ethyl groups, propyl groups, butyl groups, pentyl groups, hexyl groups, heptyl groups, and octyl groups), halogen, alkoxyl groups (e.g. methoxy groups and ethoxy groups), alkenyl groups, cyano groups, and fluorinated alkyl groups (e.g. trifluoromethyl groups)]. It is preferable that each Y is a thiophen ring, a furan ring, a pyrrole ring, and a selenophene ring. It is more preferable that each Y is a thiophen ring.
The number n is 0 to 20 preferably, and is 1 to 8 more preferably.
X and Y can bind in segments, in random order, or alternatively.
X and Y can be connected by a single bond, a double bond, or a triple bond.
Some X can take ring-fused structures.
It is favorable that X and Y bind alternatively via a single bond.]

Among chemical compounds shown in Eq. (I), the chemical compounds shown in Eq. (II) are favorable as follows.

(X)ₘ Eq. (II)

[The chemical compounds in Eq. (II) corresponds to those of n=0 in Eq. (I). X and m are specified as explained in Eq. (I). X can take ring-fused structures or bind each other via a single bond.]

It is more preferred that X is a benzene ring. In particular, such chemical compounds are exemplified by tetracene (see Chemical formula 1), pentacene (see Chemical formula 2), quaterphenyl (see Chemical formula 3), quinquephenyl (see Chemical formula C4), and sexiphenyl (see Chemical formula 5).

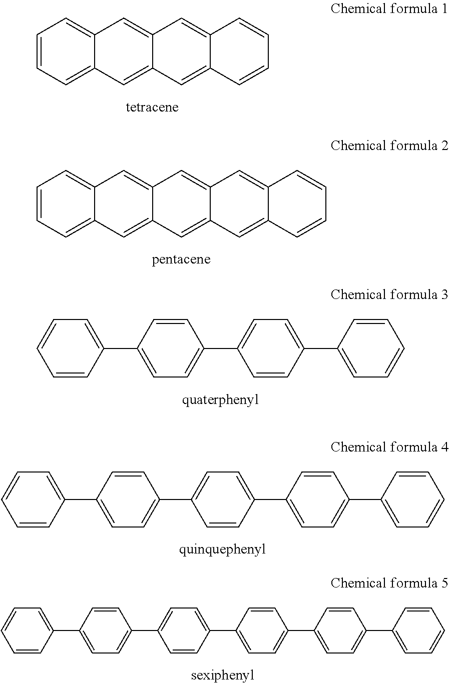

Among chemical compounds shown in Eq. (I), the chemical compounds shown in Eq. (III) are preferable.

(Y)ₙ Eq. (III)

[The chemical compounds in Eq. (III) correspond to those of m=0 in Eq. (I). Y and n are specified as explained in Eq. (I). Y binds each other via a single bond.]

It is more preferable that Y is a thiophene ring and Y bind each other through 2,5 positions.

Specifically, such chemical compounds are exemplified by quaterphenyl (see Chemical formula 6), sexiphenyl (see Chemical formula 7), and octiphenyl (see Chemical formula 8).

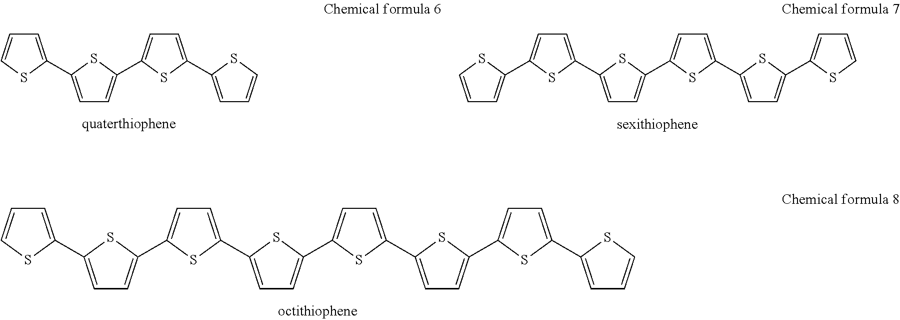 [SMILES: c1csc(-c2ccc(-c3ccc(-c4cccs4)s3)s2)c1 ; c1csc(-c2ccc(-c3ccc(-c4ccc(-c5ccc(-c6cccs6)s5)s4)s3)s2)c1 ; c1csc(-c2ccc(-c3ccc(-c4ccc(-c5ccc(-c6ccc(-c7ccc(-c8cccs8)s7)s6)s5)s4)s3)s2)c1]

Among chemical compounds shown in Eq. (I), the chemical compounds shown in Eq. (IV) are preferable.

(X)ₘ₁−(Y)ₙ−(X)ₘ₂ Eq. (IV)

[The chemical compounds in Eq. (IV) are characterized by the followings.
(i) (Y)ₙ is a segment at the center of the molecule.
(ii) Both side of (Y)ₙ, (X)ₘ₁ and (X)ₘ₁ are located.
(iii) The value m1+m2 in Eq. (IV) correspond to that of m in Eq. (I).
(iv) X, Y, and m are specified as explained in Eq. (I).
(v) X and Y bind via a single bond.]

The compounds including the following three points are more preferable.

(i) Y is a thiophene ring.
(ii) The thiophene ring binds X through 2,5 positions.
(iii) X is a benzene ring, the values m1 and m2 range 0-2, and n ranges 1-5.
If n=1 to 3, it is more preferable to be m1 and/or m2 =2.
If n is equal to or more than 4, it is more preferable to be m1 and/or m2 =1. It is preferable to be n =1 to 5.

Specifically, if n=1, such chemical compounds are exemplified by BP1T (see Chemical formula 9), BP1T-Bu (see Chemical formula 10), BP1T-OME (see Chemical formula 11), and BP1T-CN (see Chemical formula 12).

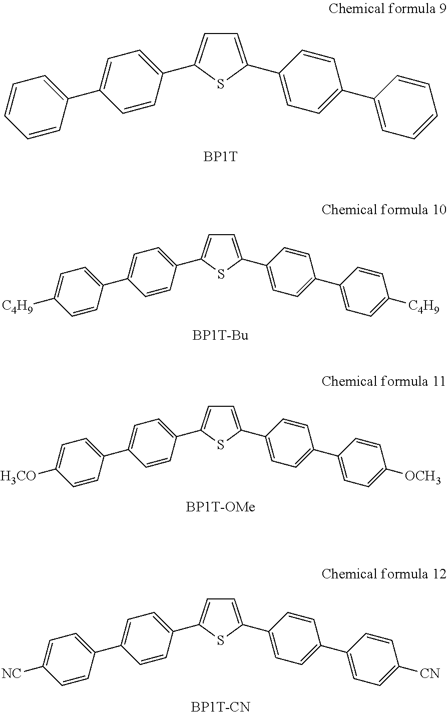

Specifically, if n=2, such chemical compounds are exemplified by BC4 (see Chemical formula 13), BP2T (see Chemical formula 14), BP1T-He (see Chemical formula 15), BP2T-OME (see Chemical formula 16), and BP2T-CN (see Chemical formula 17).

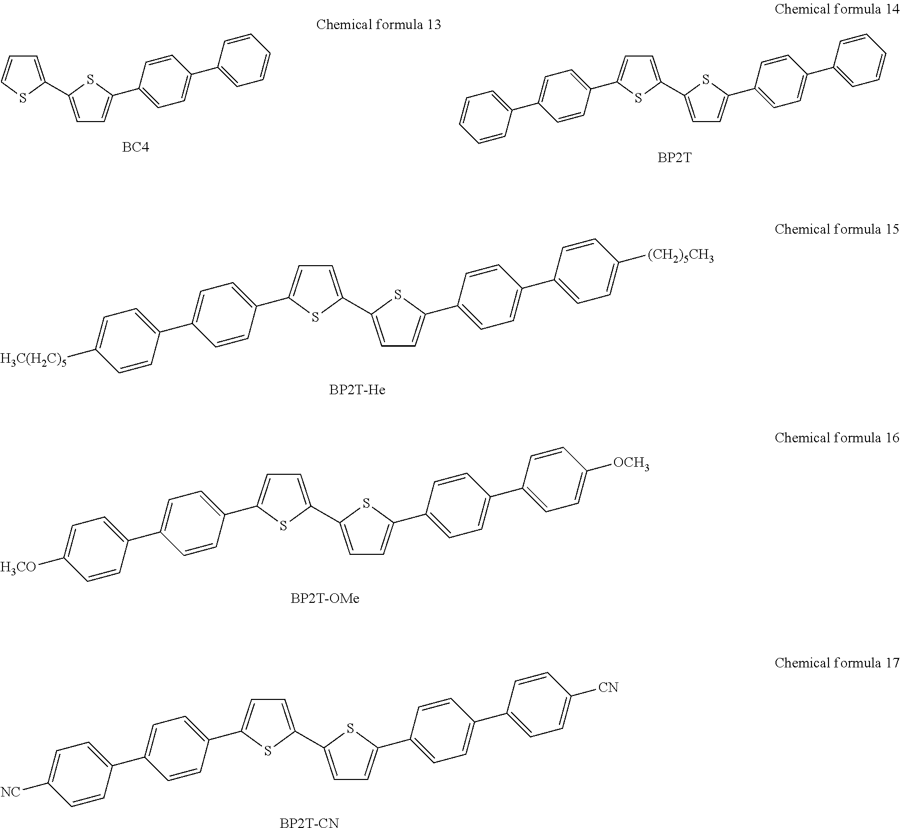

Specifically, if n=3, such chemical compound is exemplified by BP3T (see Chemical formula 18).

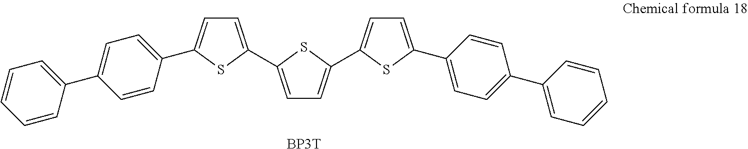

Specifically, if n=4, such chemical compounds are exemplified by BP4T (see Chemical formula 19) and P4T-CF₃ (see Chemical formula 20).

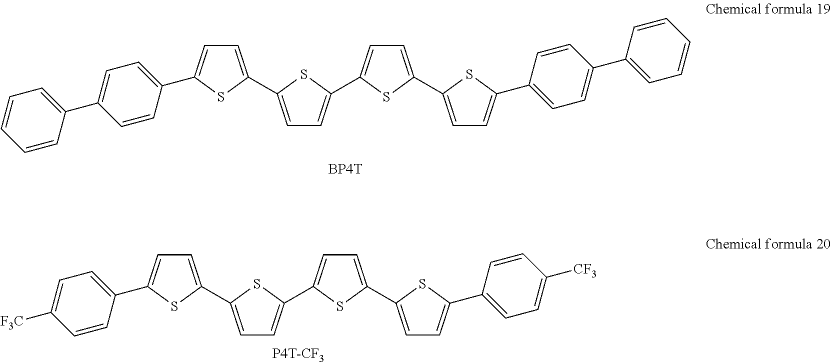

Specifically, if n=5, such chemical compounds is exemplified by P5T (see Chemical formula 21).

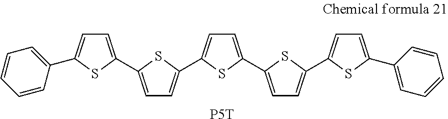

Among chemical compounds shown in Eq. (I), the chemical compounds shown in Eq. (V) are preferable.

(X)ₘ₁−(Y)ₙ₁−(X)ₘ₂−(Y)n₂−(X)ₘ₃ Eq. (V)

[The chemical compounds in Eq. (V) are characterized by the followings.
(i) The compounds in Eq. (V) correspond to those of n=2 (i.e. n1=n2=1), m=m1+m2+m3, and m2=1.
(ii) X and Y are specified as explained in Eq. (I).
(iii) X and Y bind via a single bond.]

The compounds including the following four points are preferable.

(i) Y is a thiophene ring.
(ii) The thiophene ring binds X through 2,5 positions.
(iii) Each X is an independent benzene ring and available to be independently modified with substituent groups. (iv) It is preferable that m1=m3=1 or 2, and it is more preferable that m1=m3=1.

Specifically, such chemical compound are exemplified by AC5 (see Chemical formula 22) and AC5-CF₃ (see Chemical formula 23).

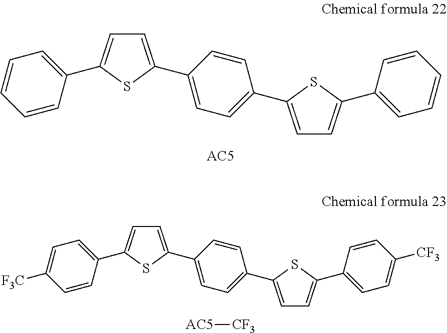

Among chemical compounds shown in Eq. (I), the chemical compounds shown in Eq. (VI) are preferable.

(X)ₘ₁−(Y)ₙ₁−(X)ₘ₂−(Y)ₙ₂−(X)ₘ₃−(Y)n₃−(X)ₘ₄ Eq. (VI)

[The chemical compounds in Eq. (VI) are characterized by the followings.
(i) The compounds in Eq. (VI) correspond to those of n=3 (i.e. n1=n2=n3=1), m=m1+m2+m3+m4, and m2=m3=1.
(ii) X and Y are specified as explained in Eq. (I).
(iii) X and Y bind via a single bond.]

The compounds including the following four points are more preferable.

(i) Y is a thiophene ring.
(ii) The thiophene ring binds X through 2,5 positions.
(iii) Each X is an independent benzene ring and available to be independently modified with substituent groups.
(iv) It is favorable that m1=m4=1 or 2, and it is more favorable that m1=m4=1.
In particular, such chemical compounds are exemplified by AC′7 (see Chemical formula 24).

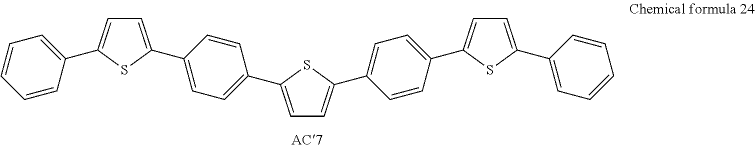 [SMILES: c1ccc(-c2ccc(-c3ccc(-c4ccc(-c5ccc(-c6ccc(-c7ccccc7)s6)cc5)s4)cc3)s2)cc1]

“Tabular crystal” of the organic semiconductor means a plate-like crystal made of the above-mentioned organic semiconductor materials, and is preferably a single crystal. Provided that the thickness is thin, the “tabular crystal” is referred to as a “slab crystal”. The thickness of the tabular crystal preferably ranges from 0.001 μm to 1000 μm, and more preferably ranges from 0.01 μm to 100 μm, and much more preferably ranges from 0.1 μm to 10 μm. The thickness of the tabular crystal is not limited as long as the intended light-emitting transistors can be obtained.

The size (or the area) of the organic semiconductor materials can be wider or narrower than, or comparable to the area occupied by the periodic structure. The size (or the area) of the tabular crystal made of the organic semiconductor materials can be wider or narrower than, or comparable to the area occupied by the periodic structure.

Methods for producing the tabular crystal made of the organic semiconductor materials cannot be limited as long as the intended crystals are available. A sublimation recrystallization method and a solution recrystallization method can be exemplified as such methods.

In the present invention, “periodic structures” are not particularly limited as long as the objective light-emitting transistors of the present invention can be obtained. The periodic structures are generally formed by concavo-convex shapes, grooves, holes, projections etc. in a uniform layer or on the principal surface of the layer. The periodic structures are also formed by two or more than two layers having different refractive indices. The periodic structures can be formed by combining the above-mentioned formation methods. “Principal surfaces” refers to a pairs of wide crystal planes.

A shape of the periodic structure viewed from a direction perpendicular to a principal surface of the layer periodic can be selected as e.g. a triangle, a tetragon, a pentagon, a hexagon, a circle, a hemicycle, and an ellipse. The preferable shape is a tetragon, and the more preferable shape is a quadrate or a rectangle. A width (or area) of the periodic structure preferably ranges from 10 μm² to 100,000 mm², and more preferably ranges from 100 μm² to 3,000 mm², and much more preferably ranges from 1,000 μm² to 100 mm².

A depth (or height) of the periodic structure preferably ranges from 0.005 μm to 100 μm, and more preferably ranges from 0.01 μm to 10 μm, and much more preferably ranges from 0.01 μm to 1 μm.

A period of the periodic structure preferably ranges from 0.01 μm to 100 μm, and more preferably ranges from 0.03 μm to 30 μm, and much more preferably ranges from 0.1 μm to 10 μm.

When the periodic structure is formed by fine concavo-convex shapes, a structure in regular intervals can be a groove, or equally-spaced holes or projections, which are linearly-expanded or linearly-aligned perpendicularly to a direction along which the periodic structure repeats its cycle.

When a structure in regular intervals is a linearly-expanded groove, a cross section of the periodic structure cut along the direction along which the periodic structure repeats its cycle can be e.g. a sinusoidal wave, a square wave, a saw-tooth wave, and a triangle wave.

When a structure in regular intervals is formed by holes or projections, its shape can be a circular cylinder, a circular cone, a polygonal cylinder, and a polygonal cone.

There are two types of periodic structures. One is a one-dimensional periodic structure where an analogous periodic structure appears at a regular interval along one particular direction. The other is a two dimensional periodic structure where two or more analogous periodic structures appear at their regular intervals in a same plane along the directions, any two of which have an angle to each other. The shape of the periodic structure is not particularly limited as long as the light emitting transistor at which the present patent aim can be obtained.

A one-dimensional diffraction grating, a multilayer film, and so on is exemplified as “the one-dimensional periodic structure”. A one-dimensional diffraction grating is preferable for the one-dimensional periodic structure.

A two-dimensional diffraction grating, a photonic crystal, and so on is exemplified as “the two-dimensional periodic structure”. A two-dimensional diffraction grating is preferable for the two-dimensional periodic structure.

The preferable periodic structure is at least one selected among a group including a one-dimensional diffraction grating, a multilayer film, a two-dimensional diffraction grating, a photonic crystal, and so on.

In the present invention, “diffraction grating” means an object which is generally called a diffraction grating. The diffraction grating is not particularly limited as long as the objective light-emitting transistor of the present invention can be obtained.

The structure of the diffraction grating can be formed by grooves or equally-spaced holes or projections, which are linearly-expanded or linearly-aligned perpendicularly to a direction along which the periodic structure repeats its cycle. The structure, length and period (or cycle) of the diffraction grating, as well as number, depth and width of the grooves of the grating are not particularly limited as long as the objective light emitting transistor of the present invention can be obtained. These can be preferably selected along with the selected organic semiconductor materials, the peak wavelength and width of the narrowed emission, the degrees of amplification and/or narrowing.

A length of the diffraction grating preferably ranges from 0.1 μm to 100,000 μm, and more preferably ranges from 1 μm to 10,000 μm, and much more preferably ranges from 10 μm to 1000 μm.

A period of the diffraction grating preferably ranges from 0.01 μm to 100 μm, and more preferably ranges from 0.03 μm to 30 μm, and much more preferably ranges from 0.1 μm to 10 μm.

A number of the grooves included in the diffraction grating preferably ranges from 3 to 1000,000, and more preferably ranges from 10 to 100,000, and much more preferably ranges from 30 to 10,000.

A depth (or a height) of the grooves included in the diffraction grating preferably ranges from 0.001 μm to 1,000 μm, and more preferably ranges from 0.003 μm to 30 μm, and much more preferably ranges from 0.01 μm to 1 μm.

A width (or a length) of the grooves included in the diffraction grating preferably ranges from 0.0001 μm to 100 μm, and more preferably ranges from 0.001 μm to 10 μm, and much more preferably ranges from 0.01 μm to 1 μm.

The periodic structure is provided anywhere in the light emitting transistor, and can be generally provided at least one principal surface of the light emitting layer. “Principal surfaces” refer to a pairs of wide planes of the light emitting layer.

When the light emitting layer is made of a tabular crystal of an organic semiconductor material, the periodic structure may be provided on at least one of principal planes of the tabular crystal. Moreover, when the light emitting layer is made of a tabular crystal of an organic semiconductor material, the principal planes mean a pair of wide crystal planes of the tabular crystal of the organic semiconductor material.

When the light emitting layer is made of a tabular crystal of an organic semiconductor material, the emitted light is more effectively amplified.

The periodic structure can be provided on the principal surface of the light emitting layer either by forming the periodic structure directly on the principal surface of the light emitting layer or by placing the periodic structure made of another material e.g. a dielectric material on the principal surface of the light emitting layer.

The methods for forming the periodic structure directly on the principal surface of the light emitting layer are not particularly limited as long as both the objective light-emitting transistors of the present invention and the above-mentioned desired periodic structure can be obtained. Some of such methods are exemplified by the method in which a groove is physically engraved, the chemical etching method, the optical method in which the refractive index modulation of the light emitting layer is induced by the interfered laser lights, the laser ablation method in which a groove is formed by absorbing the laser light, and the nano-imprint method in which a preliminary prepared mold with a periodic concavo-convex shape is pressed and shaped.

In the present invention, it is preferable that a periodic structure is formed by fabricating on a dielectric material and arranging onto the principal surface of the light emitting layer.

There is an advantage that the emission properties of the organic semiconductor materials are not degraded if the periodic structure is fabricated on the dielectric material and arranged onto the principal surface of the light emitting layer.

It is preferable that the light emitting layer is made of the tabular crystal of the organic semiconductor material.

It is preferable that the periodic structure is the diffraction grating.

It is more preferable that the light emitting layer is made of the tabular crystal of the organic semiconductor material and the periodic structure is the diffraction grating.

“Dielectric materials” are those generally referred to as dielectrics. The dielectric material is not particularly limited as long as the objective light-emitting transistor of the present invention can be obtained. It is preferred that the dielectric material is transparent to the emission light and the refractive index of the dielectric material is smaller than that of the organic semiconductor material. The refractive index difference between the organic semiconductor material and the dielectric material more preferably ranges from 0.01 to 10, and much more preferably ranges from 1 to 10. The dielectric materials are exemplified by quartz, soda glass, polymethyl methacrylate, polystyrene, polyethylene terephthalate, indium tin oxide, silicon, insulating photoresist material, insulating resist material, and so on. The preferable dielectric materials are quartz, soda glass, indium tin oxide, insulating photoresist material, insulating resist material and so on.

The methods for forming the periodic structure on the surface of the dielectric material are not particularly limited as long as both the objective light-emitting transistors of the present invention and the above-mentioned desired periodic structure can be obtained. Examples of such methods include the method in which a groove is physically engraved, the chemical etching method, the optical method (the interference exposure method) in which the refractive index modulation of the light emitting layer is induced by the interfered laser lights, the laser ablation method in which a groove is formed by absorbing the laser light, the nano-imprint method in which a preliminary prepared mold with a periodic concavo-convex shape is pressed and shaped.

For example, provided that the dielectric material is a quartz substrate, the method in which a groove is physically engraved is preferable. Provided that the dielectric material is an insulating photoresist film, the interference exposure method is preferable. Provided that the dielectric material is an insulating resist film, the nano-imprint method is preferable.

The grooves and/or holes for forming the periodic structure on the dielectric material can be penetrated or not through the dielectric material.

The periodic structure obtained by the above-mentioned process is arranged on the principal surface of the light emitting layer. The methods for arranging the periodic structure on the principal surface of the light emitting layer are not particularly limited as long as both the objective light-emitting transistors of the present invention can be obtained. In general, the dielectric material on which the periodic structure is formed is physically attached tightly to the light emitting layer by bringing the light emitting layer into contact with the dielectric material. If necessary, the dielectric material and the light emitting layer can be attached with glue. The method for arranging the light emitting layer on the surface of the dielectric material on which the periodic structure is formed is preferable because the light emitting layer is mechanically supported by the dielectric material.

It is preferable that the above-mentioned dielectric materials are used for a gate insulator of the light emitting transistor. The periodic structure can be directly formed on the gate insulator, or the dielectric material on which the periodic structure is formed can be arranged on the surface of the light emitting layer located on the opposite side of the gate insulator.

Formation of the periodic structure on the gate insulator has a beneficial effect.

The above-mentioned periodic structure can be formed on the surface of the electrodes also. The electrodes can be chosen from any of the gate, source and drain electrodes. It is preferable that the electrode is the gate electrode.

The above-mentioned source and drain electrodes are used for applying voltages to the light emitting layer and for injecting electrons and/or holes into the above-mentioned light emitting layer. These electrodes are formed by e.g. gold (Au), platinum (Pt), silver (Ag), aluminum (Al), magnesium-gold alloy (MgAu), magnesium-silver alloy (MgAg), aluminum-lithium alloy (AlLi), calcium (Ca), rubidium (Rb), cesium (Cs), and so on.

The source and drain electrodes are arranged so as to face each other and to be separated for the predefined distance, and so as to contact the light emitting layer. The distance is not particularly limited as long as the objective light-emitting transistor of the present invention can be obtained. This distance preferably ranges from 0.1 μm to 500 μm, and more preferably ranges from 1 μm to 100 μm, and much more preferably ranges from 5 μm to 50 μm.

To form the source and drain electrodes, the same metal can be selected or the different metals favorable for the carrier injection can be selected for ease in the carrier injection.

The source and drain electrodes can be formed so as to cover or sandwich the periodic structure, or be separated from the same.

The gate electrode is used for applying a voltage that controls an electric field in the light emitting layer. The gate electrode is formed by e.g. gold (Au), platinum (Pt), silver (Ag), aluminum (Al), magnesium-gold alloy (MgAu), magnesium-silver alloy (MgAg), aluminum-lithium alloy (AlLi), calcium (Ca), rubidium (Rb), cesium (Cs), and so on.

Provided that the gate insulator is silicon dioxide formed on silicon, the gate electrode can be made of silicon.

The gate electrode is arranged on the opposite side of the source and drain electrodes. Between the gate electrode and the source and drain electrodes, the gate insulator is arranged or both the gate insulator and the light emitting layer are arranged.

Therefore, the fabrication method of the light emitting transistors is provided by the present invention including:

(i) a step of preparing a light emitting layer made of an organic semiconductor material,
(ii) a step of forming a periodic structure on a surface of an dielectric material, and
(iii) a step of arranging the light emitting layer on the surface of the dielectric material.

The above-mentioned fabrication method includes a further step of arranging a gate electrode in contact with the light emitting layer via the above-mentioned dielectric material or another dielectric material, and arranging source and drain electrodes in electrical contact with the light emitting layer.

The fabrication method of the light emitting transistors is provided by the present invention including:

(i) a step of preparing a light emitting layer made of an organic semiconductor material and
(ii) a step of forming a periodic structure on a surface of the light emitting layer.

The above-mentioned fabrication method includes a further step of arranging a gate electrode in contact with the light emitting layer via a dielectric material, and arranging source and drain electrodes in electrical contact with the light emitting layer.

With regard to the light emitting transistor obtained as presented the above, the emission spectrum is measured by applying the direct current voltages to the source and drain electrodes and applying the alternating current voltage to the gate electrode. Surprisingly, the intensity of the light emission becomes increased and/or the line width of the light emission spectrum becomes narrowed compared to those of a light emitting transistor without the periodic structure. The intensity increment and the line width narrowing can be controlled more reproducibly, stably and easily even under repeated measurement. These types of phenomenon, in which the intensity increment and the line width narrowing of the emission light can be controlled more reproducibly, stably and easily under applying the direct current voltages to the source and drain electrodes and applying the alternating current voltage to the gate electrode, are exceedingly remarkable.

Hence the light emitting transistor of the present patent is allowed to be used in the after-mentioned method in which the light emitted under applying the alternating current voltage to the gate electrode is controlled more reproducibly, stably and easily and supplied as the light emission with the intensity increment and with the line width narrowing. In that case, in the after-mentioned method to produce light emission, steps of (i)-(iii) all together can be a step of preparing a light emitting transistor of the present invention. In the step of preparing a light emitting transistor of the present patent, a light emitting transistor of the present invention can be formed on the basis of the above-mentioned fabrication method as necessary, or the preliminarily-fabricated light emitting transistor can be used. It is preferable that the DC voltages are applied to the source and drain electrodes.

The method for producing the light emission with the intensity increment and/or with the line width narrowing of the present invention includes:

(i) a step of preparing a light emitting layer,
(ii) a step of providing a periodic structure with at least one principal surface of the light emitting layer,
(iii) a step of arranging source, drain and gate electrodes, and
(iv) a step of applying an alternating current voltage to the gate electrode.

That is to say, the method for producing the light emission with intensity increment and/or with line width narrowing includes the step (iv) in addition to the steps (i)-(iii). In the step (iv), the light emission is generated in the light emitting layer by applying an electric field to the light emitting layer.

In the present invention, the term “amplification (or increment)” means enlarging the emission intensity (or the emission amplitude) of light. The amplification ratio ranges preferably from 1.2 to 1.5, and ranges more preferably from 1.5 to 4, and ranges much more preferably from 4 to 20.

In the present patent, the term “(line width) narrowing” means narrowing the wavelength width of the emission spectrum. The full-width of half maximum of the emission spectrum is preferably less than 15 nm, more preferably less than 10 nm, and much more preferably less than 5 nm.

The light emission is, generally, generated at the light emitting layer between the source and the drain electrodes, and is believed to be amplified or to be narrowed in passing through the part where the periodic structure is formed. The source and drain electrodes can be formed so as to cover or interleave the periodic structure or be separated from the structure.

In the present invention including both the light emitting transistor and the method for producing the light emission with the intensity increment and/or with the line width narrowing, the wavelength with the intensity increment and/or with the line width narrowing, the order of narrowing of the light emission, and so on can be controlled more reproducibly, stably and easily by appropriately changing a used periodic structure [e.g., the width of the periodic structure, the depth of the grooves, more especially, e.g., the period between the grooves of the grating (grating space), the length of the grooves, and the number of the grooves].

A potential difference produced by an electric field applied between the source and drain electrodes ranges preferably from 0 V to 300 V, and ranges more preferably from 25 V to 250 V, and ranges much more preferably from 50 V to 200 V.

It is preferred that an alternating current voltage is applied to the gate electrode. A frequency of the alternating current voltage applied to the gate electrode ranges preferably from 1 Hz to 50 MHz, and ranges more preferably from 10 Hz V to 5 MHz, and ranges much more preferably from 100 Hz to 500 kHz. Amplitude of the alternating current voltage applied to the gate electrode ranges preferably from 1 V to 300 V, and ranges more preferably from 5 V to 300 V, ranges much more preferably from 25 V to 250 V, and ranges most preferably from 50 V to 200 V.

The light emitting transistor of the present invention can be used in various fields. For example, the field of information device, the field of display, the field of living body optical measurement can be exemplified.

The method for producing the light emission with the intensity increment and/or with the line width narrowing of the present invention can be used in various fields. For example, the field of information device, the field of display, the field of living body optical measurement can be exemplified.

### DESCRIPTION OF EMBODIMENT

The present invention will be described below more concretely with reference to attached drawings, and these embodiments are merely for illustrative purposes and are not meant to be limiting on the present invention without departing from the scope of the present invention.

### First Embodiment

### (A Light Emitting Transistor According to a First Embodiment)

A light emitting transistor according to a first embodiment and a fabrication method of the light emitting transistor are illustrated with referring to a schematic view in FIG. 1, a cross sectional view from the horizontal direction in FIG. 1a, and a cross sectional view from front direction in FIG. 1b for the light emitting transistor according to the first embodiment.

The light emitting transistor 10 is composed of an organic semiconductor crystal 11, a pair of electrodes 14, a silicon dioxide layer 15, and a silicon layer 16. The electrodes 14 formed on the dioxide layer 15 consist of a chromium layer 14a and a gold layer 14b. A diffraction grating 13 is formed on a part of the dioxide layer 15. A silicon substrate 12 is composed of the pair of electrodes 14, the dioxide layer 15, and the silicon layer 16. The dioxide layer 15 functions as a gate insulator layer. The organic semiconductor crystal 11 is laminated on both the pair of electrodes 14 and the dioxide layer, which are in physical contact with the organic semiconductor crystal 11.

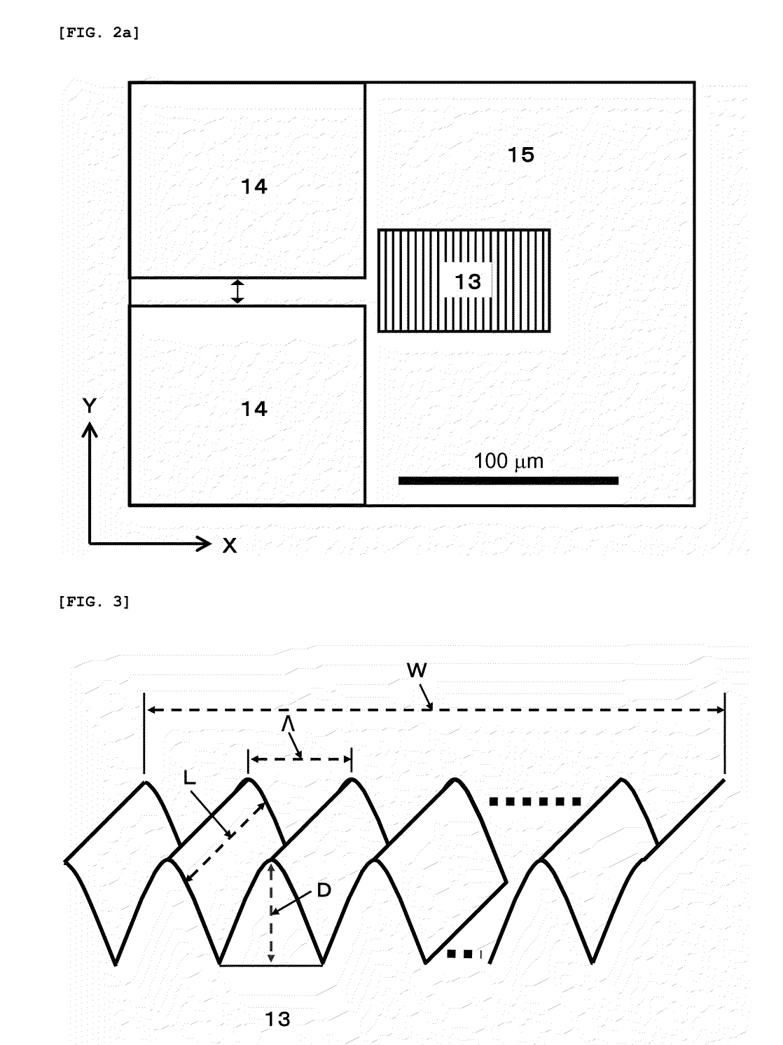

FIG. 2 shows a micrograph of the device substrate 12 around the diffraction grating and a part of the pair of electrodes 14. FIG. 2a shows a pattern diagram of the above-mentioned silicon substrate 12. The electrodes made of chromium and gold are recognized at the upper left and the lower left of the micrograph. The topmost surfaces of the electrode presented in the micrograph are gold. The distance between the upper and lower electrodes, indicated by means of double-headed arrows in FIGS. 2 and 2a, defines the channel length (10 μm). The diffraction grating 13 is recognized at the center part of the micrograph. The grooves of the diffraction grating are engraved along the vertical direction. (Thus, the diffraction grating wave vector is parallel to the lateral direction.) The organic light emitting transistor 10 shown in FIG. 1 was fabricated as follows.

### Formation Process of the Diffraction Grating on the Device Substrate

A device substrate (0.5 cm×1 cm in size) was beforehand prepared by sequentially depositing chromium (5 nm in thickness) and gold (100 nm in thickness) to form a pair of electrodes. Each electrode was a rectangle of 2 mm×1.5 mm in size, and the pairs of electrodes were placed so that their distance is 10 μm. One electrode functions as a source contact and the other was used for a drain contact. The channel was formed at the area between the mutually opposed source and drain electrodes.

The distance between both ends of source and drain electrodes through the channel is referred to as the channel length, and the distance along the electrode edges in contact with the channel is referred to as the channel width. This device substrate makes it possible to fabricate the organic field-effect transistor having the maximum channel length of 10 μm and the maximum channel width of 2 mm: The former is a distance between the electrodes along y-direction in FIG. 2a and is expressed by the double-headed arrow, and the latter is the length on the electrode along x-direction in FIG. 2a. The surface of the device substrate was cleaned with acetone in an ultrasonic bath for 10 min.

The device substrate was secured to a sample stage of a focused ion beam (FIB) system with an aluminum foil conductive tape, and was then inserted into the fabrication chamber of the system with keeping the chamber high vacuum.

Keeping the chamber high vacuum (less than 8×10⁻⁴ Pa), the diameter of gallium ion beam was adjusted to be 70 nm. After setting 50-fold magnification of the FIB system, the engraving place was determined from the surface observation of the device substrate as follows.

The edges of the pair of the source and drain electrodes in contact with the channel form a pair of two parallel or almost parallel line segments. (These line segments are parallel or almost parallel to the x-direction in FIG. 2a.) The diffraction grating was engraved at the place which was sandwiched between two straight lines formed by extending the pair of two line segments, and which place at least partly overlapped with the surface of the silicon substrate with electrodes in a direction away from the channel, the drain electrode and the source electrode along the channel width direction. The direction of the grating of the diffraction grating is perpendicular or almost perpendicular to the above pair of two straight lines. (Therefore the grating wave vector is parallel or almost parallel to the two straight lines.)

The length L along the groove of the diffraction grating can be longer or shorter than, or comparable with the distance between the source and drain electrodes (i.e. the channel length). It is preferred that the length L is longer than the channel length. It is preferred that the diffraction grating is engraved so that the grooves of the diffraction grating just or completely pass over the above-mentioned place along the channel length direction.

After the determination of the engraving place, the diffraction grating was engraved using the following conditions.

After setting 1200-fold magnification of the FIB system, the groove was engraved to from the grating on the device substrate under the FIB system conditions of the engraving length L of 50 μm and the dose amount of 1.0 nC/(μm)² using the line mode for the fabrication mode.

Using the same engraving conditions the grooves were engraved at equal distances so that these grooves are parallel to one another. The distance between one point and the next point to start engraving groove was set to 3 pixels on the screen under 1200-fold magnification of the FIB system. FIG. 3 shows a perspective view of the diffraction grating 13 obtained by the above-mentioned method. The length L along the groove of the diffraction grating was longer than the distance between the source and drain electrodes (i.e., the channel length), and the diffraction grating was engraved so as to completely pass over the above-mentioned place along the channel length direction.

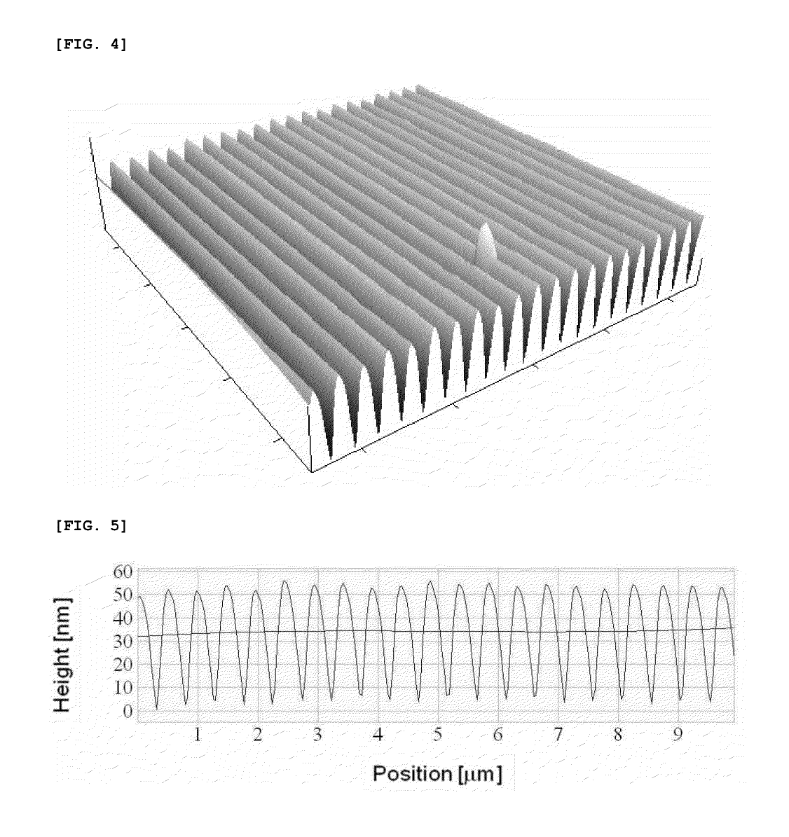

FIG. 4 shows the atomic force microscope (AFM) image indicating a part of a three-dimensional image of the diffraction grating 13 on the silicon substrate 12 with the electrodes 14. FIG. 5 shows a vertical cross section of the diffraction grating cut from FIG. 4 along the direction perpendicular to the groove (parallel to the diffraction grating wave vector).

From microscope observation of the obtained diffraction grating, it was confirmed that the length L along the grooves was 46.6 μm and the length W perpendicular to those grooves was 78.8 μm. The period A between adjacent grooves was determined to be 492.2 nm. The AFM observation decided the depth of the grooves to be 47.7 nm.

### Fabrication of Slab Crystals of Organic Semiconductor Materials Through the Sublimation Recrystallization Method

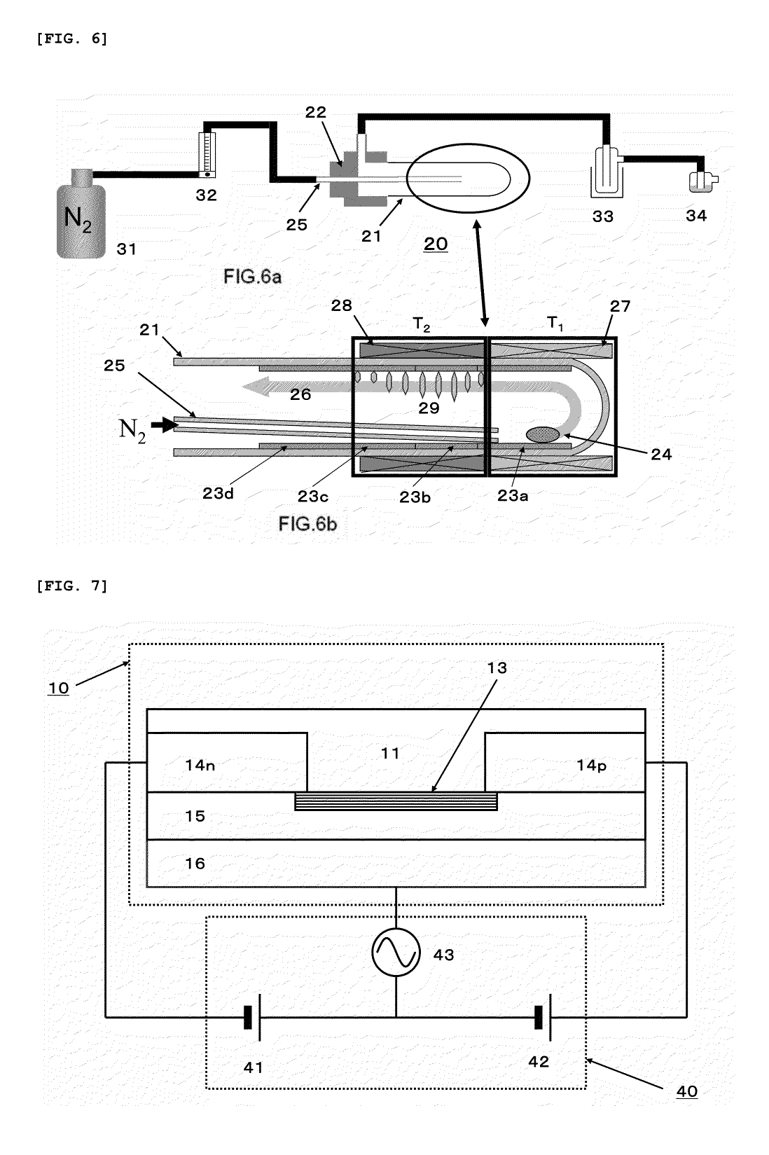

Organic crystals were grown by the sublimation recrystallization method. FIG. 6 shows a schematic diagram of a sublimation recrystallization apparatus. FIG. 6 schematically indicates an overall view of the sublimation recrystallization equipment 20. The sublimation recrystallization equipment 20 contains a test tube 21 in which the material is evaporated and recrystallized, a set of a nitrogen gas cylinder 31 and a flow meter 32 both of which were used for introducing nitrogen into the tube 21 to prevent the material degradation, a cold trap 33 which collects the material gas out of the recrystallization, and a bubbler 34 including liquid paraffin.

FIG. 6b schematically shows a detailed diagram of the test tube 21 in which the organic semiconductor material is sublimed and recrystallized. The test tube 21 (25 mm in external diameter) is highly-sealed with a stainless-steel jig using two pairs of a stainless-steel ring and a rubber ring. The glass rings 23 (22 mm in external diameter) were inserted into the test tube 21 so as to make it easy to eject and collect the grown crystals. Four glass rings of 30, 20, 20, and 30 mm in length were placed into the test tube 21 from its bottom.

The organic semiconductor material powder 24 was put onto the innermost glass tube 23a. As the organic semiconductor material AC′7, shown as chemical formula 24, was selected. Nitrogen gas flow was controlled by the flow meter 32, and was introduced into the test tube 21 through the thin glass tube 25 (4 mm in external diameter) attached onto the stainless-steel jig. The nitrogen gas 26 also functioned as a carrier gas for the vaporized organic material by heat.

Two heaters, the source heater 27 and the growth heater 28, were used for sublimation of the organic semiconductor material powder 24 and recrystallization, respectively. The bottom part of the test tube 21 was wrapped with the source heater 27 so as to cover the innermost glass ring 23a. The test tube 21 was also wrapped with the growth heater 28 so as to cover the glass rings 23b and 23c. Hereby, the area of the test tube 21 wrapped with the source heater 27 is termed “source zone”, and the area of the test tube 21 wrapped with the growth heater 28 is termed “growth zone”. The organic semiconductor material powder 24 is heated and sublimed at the source zone, and is recrystallized at the growth zone, producing the organic semiconductor crystals 29. The temperatures of the source and growth heaters are termed T_{1 and T}₂, and were set to 360° C. and 310° C. to 330° C., respectively. The crystal growth was carried out for 4 h40 min-13 h.

Both the nitrogen gas 26 and the vapor of the uncrystallized organic semiconductor material are vented from the test tube 21. The semiconductor material vapor is removed at the cold trap 33. The nitrogen gas goes out to the atmosphere through the bubbler 34.

Reference Document 1 discloses the crystal growth method using the sublimation recrystallization.

Reference Document 1 : T. Yamao, S. Ota, T. Miki, S. Hotta, and R. Azumi, Thin Solid Films, 516 (2008) 2527-2531.

Fabrication of Light Emitting Transistors by Laminating Slab Crystals of the Organic Semiconductor Materials onto Device Substrates

An appropriate slab crystal was selected from among many organic semiconductor crystals grown using the above-mentioned sublimation recrystallization method. The silicon substrate 12 with the electrodes 14 in which the grating 13 was engraved was cleaned with acetone, 2-propanol, and ethanol in the ultrasonic cleaner for 10 min each, and was cleaned using UV-ozone cleaner for 5 min.

The organic semiconductor crystal 11 was mounted on, and was in physical contact with the silicon substrate 12 with the electrodes 14 so that the crystal entirely covered the diffraction grating 13 and overlapped with the couple of the electrodes 14. To secure the contact between the electrodes 14 and the organic semiconductor crystal 11, a drop of ethanol (40° C.) was put between them, and was dried. As a result, the light emitting transistor 10 was fabricated so that the slab crystal of the organic semiconductor crystal 11 was closely connected to the electrodes 14 and the dioxide layer 15 including the grating 13.

### Spectrally Narrowed Emissions Under Applying the Square-Wave Alternating-Current Voltages to the Gate Contact

FIG. 7 shows a schematic diagram of the driving circuit that operates the light emitting transistor. The circuit 40 for driving the light emitting transistor 10 contains DC power supplies 41 and 42, and an AC power supply 43. The DC power supply 41 applies the negative DC voltage V_{S} to one electrode (the source contact) 14n of a pair of the electrodes. The DC power supply 42 applies the positive DC voltage V_{D} to the other electrode (the drain contact) 14p of that pair of the electrodes. The AC power supply 43 applies the alternating-current voltage V_{G} to the silicon layer (the gate contact) 16. The DC voltage applied between the source and drain contacts mainly contribute to the carrier transport and the carrier recombination in the organic semiconductor crystal 11. The voltage applied to the gate contact contributes to the carrier injection into the organic semiconductor crystal 11. The light emitting transistor 10 in FIG. 7 corresponds to the light emitting transistor 10 in FIG. 1a which is the cross section viewing from the right hand side of the light emitting transistor 10 in FIG. 1.

The patent document WO2009/099205A1 discloses the method applying the square-wave alternating-current voltage to the gate contact.

Under applied voltages to the light emitting transistor 10, the detector (photonic multichannel analyzer, henceforth, called “PMA”) observed through the medium of an optical fiber the emissions from the light emitting transistor 10, which emissions radiated along the direction parallel to both the crystal plane of the organic semiconductor crystal 11 on the light emitting transistor 10 and the grating wave vector of the diffraction grating 13, and which emissions radiated from the edge face of the slab crystal located on opposite side of the electrodes 14 from the area of the diffraction grating 13.

For example, the emissions were observed from the right hand side of the organic semiconductor crystal 11 with regard to the light emitting transistor in FIG. 1 and from the front side of the organic semiconductor crystal 11 with regard to the light emitting transistor in FIG. 7.

Reference Document 2 discloses the positional relationship between the organic light emitting transistor and the detector.

Reference Document 2: T. Yamao, K. Terasaki, Y. Shimizu, and S. Hotta, J. Nanosci. Nanotechnol., 10 (2010) 1017-1020

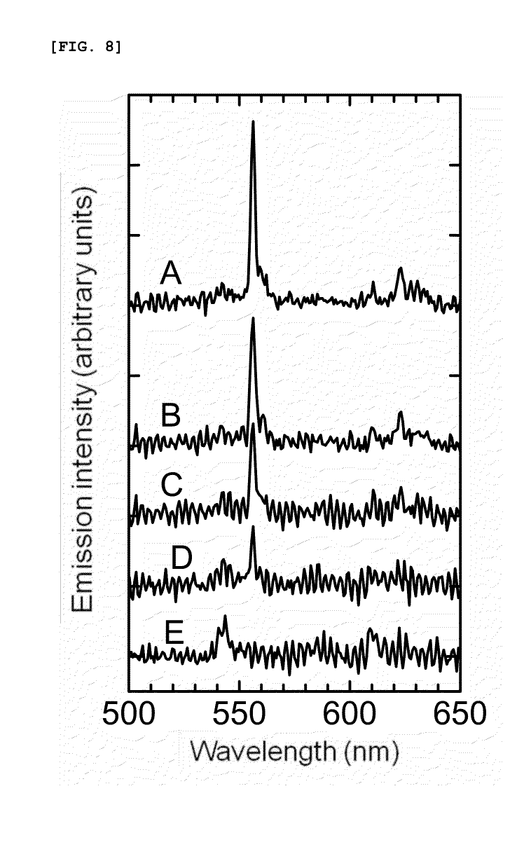

FIG. 8 shows the emission spectra from the above-mentioned light emitting transistor 10 operated under applying square AC voltages as the AC voltages to the gate contact. The emission intensities were plotted as a function of wavelength. TABLE 1 summarizes the specific values of the source voltage V_{S}, the drain voltage V_{D}, the AC gate voltage amplitude V_{G}, and the frequency of the AC gate voltage.

TABLE 1

| Symbol | Drain | Source | Gate voltage | Gate voltage |
|---|---|---|---|---|
| in | voltage | voltage | amplitude | frequency |
| FIG. 8 | (V) | (V) | (V) | (kHz) |
| A | 70 | −70 | 100 | 20 |
| B | 70 | −70 | 95 | 20 |
| C | 70 | −70 | 90 | 2 |
| D | 60 | −60 | 80 | 2 |
| E | 30 | −30 | 30 | 2 |

As shown in FIG. 8, spectrally-narrowed emissions, i.e. the emissions with markedly narrow spectrum width, were observed at particular applied voltage conditions from A to D. The emission peak intensity increased with the magnitude of V_{D}, V_{S}, and V_{G}. In the spectrum A, the peak position and the full-width at half maximum of the dominant narrowed emission were 556.3 nm and 2.05 nm, respectively.

The secondary peak was found at 623.2 nm.

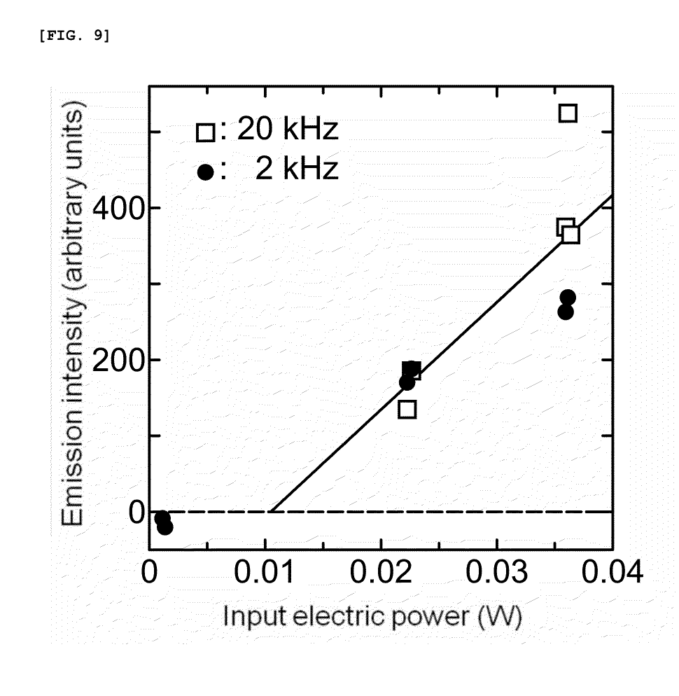

FIG. 9 indicates the emission peak intensities located at 556.3 nm of the narrowed emission from the light emitting transistor 10, and is plotted as a function of the input power into the light emitting transistor 10. FIG. 9 includes the both results measured at the AC gate frequencies 2 kHz and 20 kHz. The emission intensity shows 0 counts at around the input power of 0.01 W when the data points having the emission intensities more than 100 counts were approximated by straight-line. The narrowed emission from the light emitting transistor 10 has a threshold for the input power. This indicates the existence of the optical amplification effect in relation to the narrowed emission from the light emitting transistor 10.

### (First Comparison Example)

### (A Light Emitting Transistor According to a First Comparison Example)

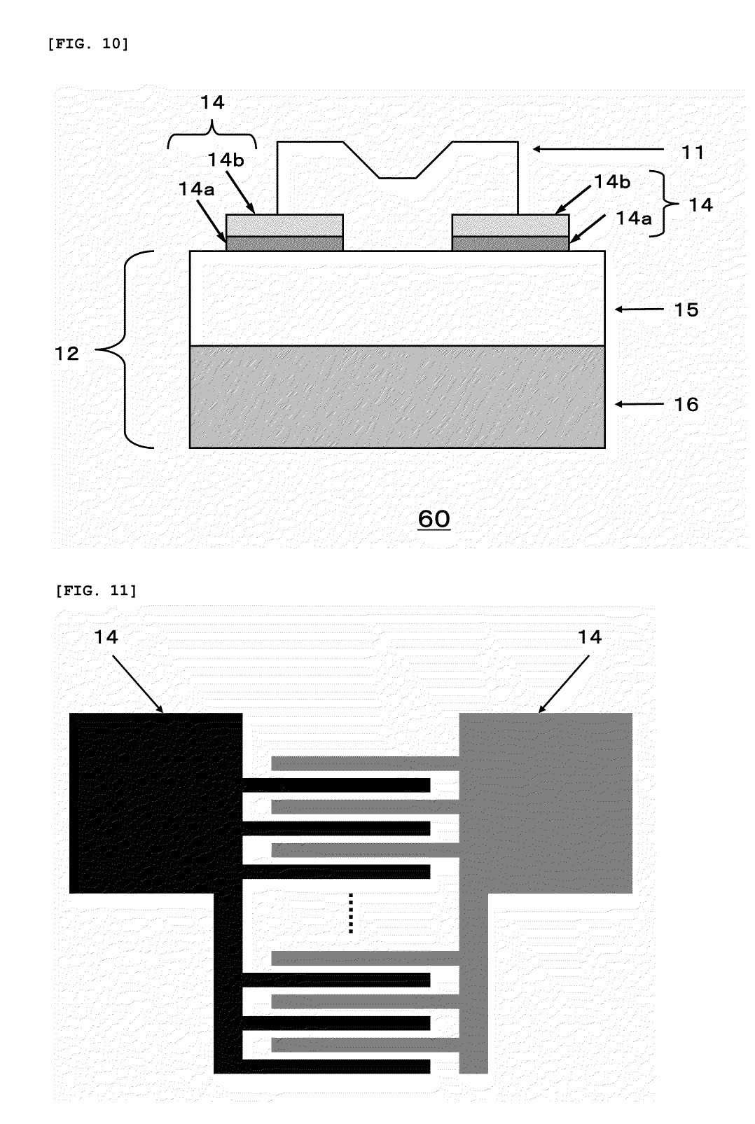

A light emitting transistor according to a first comparison example and a fabrication method of the light emitting transistor are illustrated with referring to a schematic structure of the light emitting transistor 60 according to the first comparison example in FIG. 10.

The light emitting transistor according to the first comparison example was fabricated in a manner similar to that for the above-mentioned light emitting transistor according to the first embodiment except the following two points.

(1) No grating was engraved on the silicon substrate 12 with the electrodes 14
(2) The electrodes were comb-shaped composed of the chromium layer 14a and the gold layer 14b as shown in FIG. 11.

After the silicon substrate 12 with the electrodes was cleaned with acetone, 2-propanol, and ethanol in the ultrasonic cleaner for 3 min each, was exposed to the ethanol vapor, and was cleaned using UV-ozone cleaner for 5 min, the AC′7 crystal was laminated on the silicon substrate 12 with the electrodes.

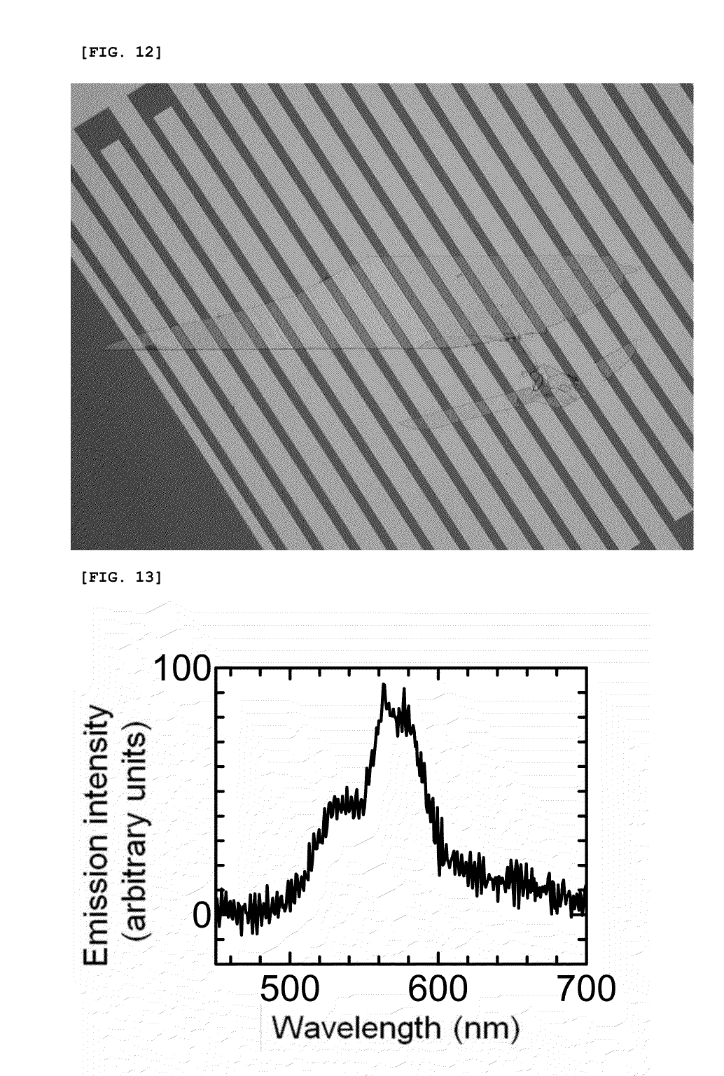

FIG. 12 shows a micrograph of thus obtained light emitting transistor 60. This micrograph was taken along the direction perpendicular to the crystal surface of the organic semiconductor crystal 11. The distance between the comb-shaped electrodes corresponds to the distance between the electrode 14, and the distance is 30 μm, corresponding to the channel length. The AC′7 crystal is located at the center of the micrograph as the transversely extended crystal enclosed with white dotted line.

The emissions from thus obtained light emitting transistor 60 under applying the voltages were observed in a manner similar to that for the light emitting transistor according to the first embodiment. Concretely, the PMA detected the emissions radiating along the direction parallel to both the crystal plane of the organic semiconductor crystal 11 on the light emitting transistor and the long direction of the thin comb-shaped electrodes.

FIG. 13 shows the emission spectrum of the light emitting transistor 60 operated under applying the square wave AC voltage to the gate electrode. DC voltage of +70 V was applied to one electrode 14, and DC voltage of −70 V was applied to the other electrode 14, and the square wave AC voltage of the amplitude 100 V and the frequency 20 kHz was applied to the gate electrode. The emission intensities were plotted as a function of wavelength. The vertical axis indicates the emission intensity per second. No narrowed emission spectrum was observed from the light emitting transistor 60.

### Second Embodiment

### (A Light Emitting Transistor According to a Second Embodiment)

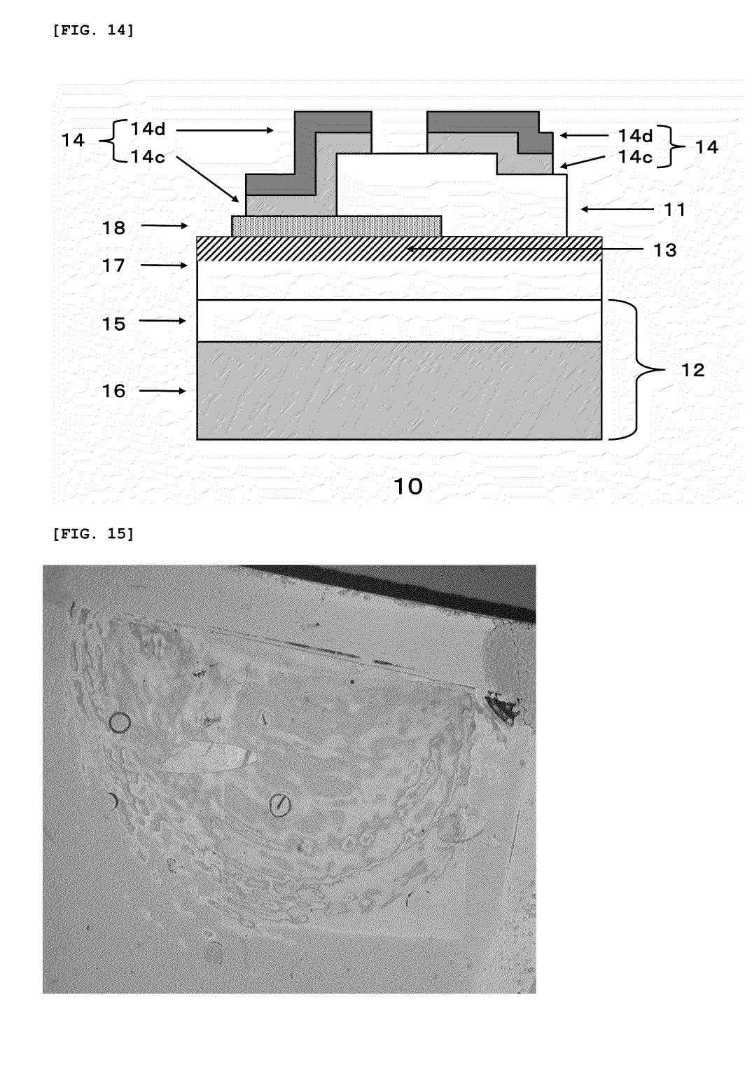

A light emitting transistor according to a second embodiment and a fabrication method of the light emitting transistor are illustrated with referring to a schematic structure of the light emitting transistor according to a second embodiment in FIG. 14.

The light emitting transistor 10 contains a silicon substrate 12 in which a silicon layer 16 and a silicon dioxide layer 15 are laminated, a photoresist layer 17 on which a diffraction grating 13 is formed, an organic semiconductor amorphous film 18, an organic semiconductor crystal 11, and a couple of electrodes 14 composed of layered magnesium-silver layer 1c and silver layer 1d.

The photoresist layer 17 is arranged on the dioxide layer 15, and the diffraction grating 13 is formed on the entire surface of the photoresist layer 17 which is located on an opposite surface having contact with the dioxide layer 15. The organic semiconductor amorphous film 18 and the organic semiconductor crystal 11 are arranged on the diffraction grating 13, and the organic semiconductor crystal 11 covers a part of the organic semiconductor amorphous film 18. One electrode 14 is arranged on the organic semiconductor crystal 11, and the other electrode is arranged to be in contact with both the organic semiconductor crystal 11 and the organic semiconductor amorphous film 18. The light emitting transistor shown in FIG. 14 was fabricated as follows.

### Fabrication of the Diffraction Grating on the Device Substrate

A silicon wafer substrate (1 cm×1 cm in size) with a dioxide layer was cleaned with acetone, 2-propanol, and ethanol in the ultrasonic cleaner for 6 min each, and dried using nitrogen blow.

After the substrate was placed on a spin-coater, drops of a cyclopentanone solution of a MicroChem photoresist SU-8 (weight ratio of cyclopentanone to SU-8 is 1:2) were put on the substrate so that the solution entirely covered the substrate surface. The photoresist layer was formed by rotating the substrate at 500 rpm for 13 s then 2000 rpm for 17 s by a spin-coater. The resulting photoresist layer was baked on a heater first at 75° C. for 7 min, then at 105° C. for 14 min to evaporate the unnecessary solvent in the photoresist layer.

The silicon substrate 12 with the dioxide layer on which the photoresist layer 17 was formed was set on an interference exposure equipment, and the interference exposure of the photoresist layer 17 was carried out using the third harmonic generation of an EKSPLA PL2143 Nd:YAG laser (wavelength: 355 nm, pulse duration: 30 ps, repetition rate: 10 Hz). The laser pulse energy was 400 μJ and the beam diameter was 6.5 mm. The incident angle of the laser light from the normal to the substrate surface was 20°, and the photoresist was exposed by the above-mentioned laser light for 4 s. To cure the exposed part of the photoresist film, the substrate including the exposed photoresist film was baked on the heater at 65° C. for 7 min first, then at 95° C. for 7 min, and was cooled to room temperature in air.

The silicon substrate 12 including the exposed photoresist layer 17 was immersed in a MicroChem SU-8 developer for 1 min in order to remove the unnecessary unexposed photoresist, and was rinsed with 2-propanol, then was dried with a dryer. The silicon substrate 12 including the developed photoresist layer 17 was baked again on the heater at 175° C. for 20 min in order to complete the curing reaction for the uncured part of the photoresist layer 17.

It was confirmed by the AFM observation of the resulting diffraction grating that the period A between adjacent grooves was 549.3 nm and the depth of the grooves D was 43 nm.

Reference Document 3 disclosed the method of fabricating the diffraction grating using the photoresist SU-8.

Reference Document 3: T. Yamao, T. Inoue, Y. Okuda, T. Ishibashi, S. Hotta, and N. Tsutsumi, Synth. Met., 15 (2009) 889-892.

AC5-CF₃, shown as chemical formula 23, was deposited in vacuum (1×10⁻³ Pa) through an evaporation mask onto the developed photoresist layer 17 arranged on the silicon substrate 12. The thickness of AC′7 was set at 70 nm. AC′7 crystal, grown in the same manner as the method described in the first embodiment, was laminated on the substrate on which the AC5-CF₃ was deposited so that the AC′7 crystal was in contact with both the parts of the diffraction grating covered with and without the AC5-CF₃ film. FIG. 15 shows a micrograph of the organic semiconductor crystal 11, which was laminated on the diffraction grating made of the photoresist, taken from the direction normal to the substrate surface. The diffraction grating 13 made of the photoresist layer 17 is within the semicircle area bounded by a dashed line, and the AC5-CF₃ film on the photoresist layer 17 is located within the square area bounded by a dotted line. The AC′7 crystal is located within the area bounded by a solid line.
Electrode Fabrication onto the Crystal Arranged on the Diffraction Grating

A tungsten wire (around 50 μm in diameter) was arranged on the AC′7 crystal 11 laminated on the diffraction grating 13 made of the photoresist layer 17 covering the silicon substrate 12 with the dioxide layer so that the wire was parallel to the boundary line between the evaporated (amorphous) AC5-CF₃ film 18 and the photoresist layer 17. This wire was attached on the AC′7 crystal 11 laminated on the AC5-CF₃ film 18. The direction of the wire was also parallel to the grating wave vector of the diffraction grating 13. Alloy layers of magnesium and silver 14c were formed on the both sides of the surface of the AC′7 crystal 11 divided by the tungsten wire through vacuum-depositing magnesium and silver with their mass ratio of 1:1. Then, silver layers 14d were formed on both the alloy layers of magnesium and silver 14c divided by the tungsten wire. The width of the tungsten wire decides the electrode separation (the channel length). The alloy layers 14c of magnesium and silver and the silver layers 14d combined and functioned as the electrodes 14. As stated above, the light emitting transistor according to the second embodiment was fabricated.

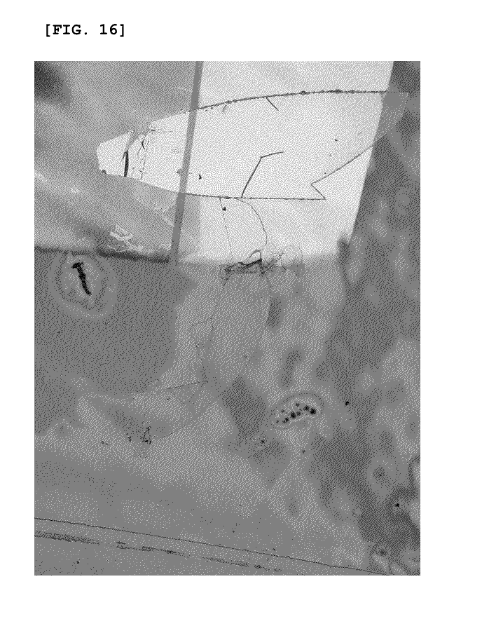

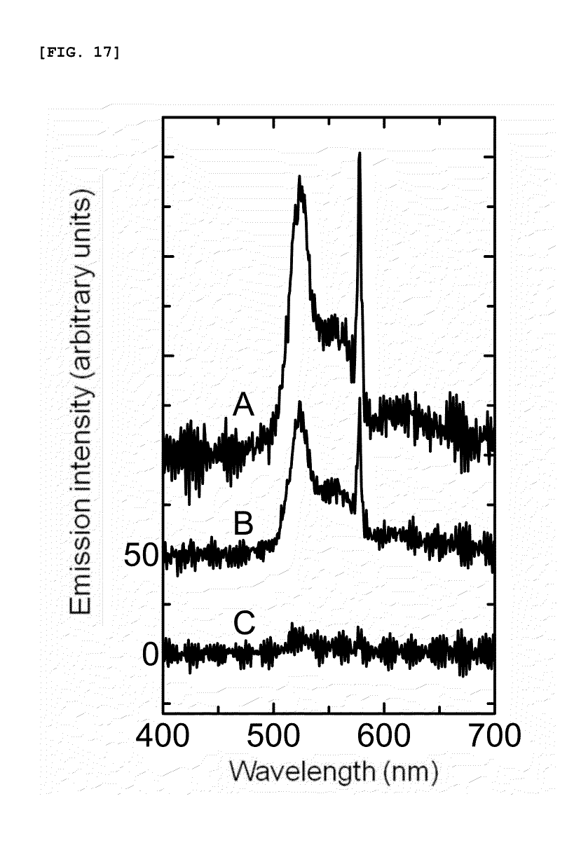

FIG. 16 shows a micrograph of the light emitting transistor 10. The area between the two silver electrodes 14 forms the channel.

### Spectrally Narrowed Emissions Under Applying the Square-wave Alternating-Current Voltages to the Gate Contact

The current-excited emission spectra of the light emitting transistor 10 according to the second embodiment were observed in a way similar to that for the first embodiment. FIG. 17 shows the emission spectra of the light emitting transistor 10 according to the second embodiment operated under applying as the gate voltage V_{G} the square-wave AC voltage. TABLE 2 summarizes the specific values of the source voltage V_{S}, the drain voltage V_{D}, The AC gate voltage amplitude V_{G}, and the frequency of the AC gate voltage.

TABLE 2

| Symbol | Drain | | Gate voltage | Gate voltage |
|---|---|---|---|---|
| in | voltage | Source | amplitude | frequency |
| FIG. 17 | (V) | voltage (V) | (V) | (kHz) |
| A | 100 | −100 | 110 | 100 |
| B | 80 | −80 | 90 | 50 |
| C | 70 | −90 | 90 | 2 |

As shown in FIG. 17, spectrally-narrowed emissions, i.e. the emissions with markedly narrow spectrum width, were observed at particular applied voltage conditions of A and B. In the spectrum A, the peak position and the full-width at half maximum of the narrowed emission were 577.7 nm and 4.58 nm, respectively.

### Third Embodiment

### (A Light Emitting Transistor According to a Third Embodiment)

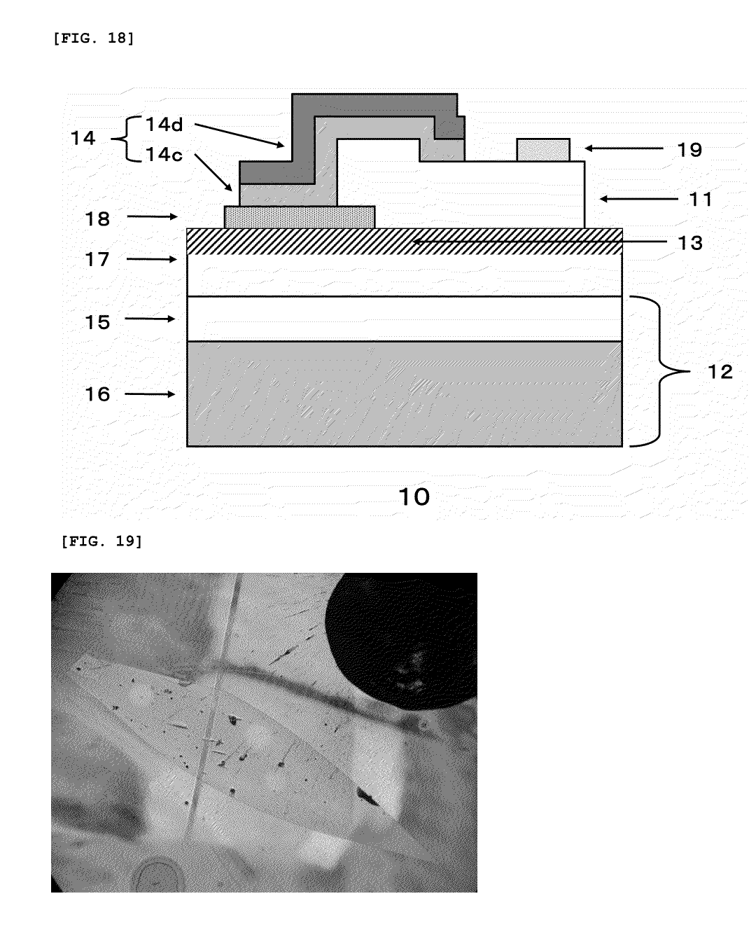

A light emitting transistor according to a third embodiment and a fabrication method of the light emitting transistor are illustrated with referring to a schematic structure of the light emitting transistor according to a third embodiment in FIG. 18.

The light emitting transistor according to the third embodiment was fabricated in a manner similar to that for the above-mentioned light emitting transistor according to the second embodiment except the following 2 points.

(1) The channel was formed on the AC'7 crystal mounted on the diffraction grating made of the photoresist layer 17.
(2) The Au electrode was formed on the AC'7 crystal 11 from the one side of the tungsten wire.

It was confirmed by the AFM observation of the resulting diffraction grating that the period A between adjacent grooves was 528.2 nm.

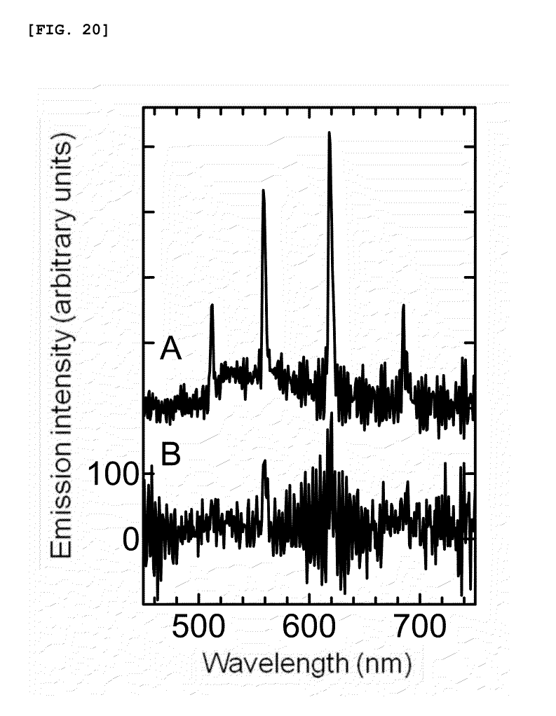

FIG. 19 shows a micrograph of the light emitting transistor 10. The area between the silver electrode 14d and the gold electrode 19 forms the channel. The AC′7 crystal 11 is leaf-shaped at the center of the micrograph. The longitudinally-extending channel located at the center of the AC′7 crystal 11 corresponds to the distance between the electrodes 14d and 19. The thin electrode 14 was recognized at the left side of the channel and the thin electrode 19 was recognized at the right side of the channel.

### Spectrally Narrowed Emissions Under Applying the Square-Wave Alternating-Current Voltages to the Gate Contact

The current-excited emission spectra of the light emitting transistor 10 according to the third embodiment were observed in a way similar to that for the first embodiment. FIG. 20 shows the emission spectra of the light emitting transistor 10 according to the third embodiment operated under applying as the gate voltage V_{G} the square-wave AC voltage. TABLE 3 summarizes the specific values of the source voltage V_{S}, the drain voltage V_{D}, the AC gate voltage amplitude V_{G}, and the frequency of the AC gate voltage.

TABLE 3

| Symbol | Drain | | Gate voltage | Gate voltage |
|---|---|---|---|---|
| in | voltage | Source | amplitude | frequency |
| FIG. 20 | (V) | voltage (V) | (V) | (kHz) |
| A | 60 | −60 | 90 | 50 |
| B | 60 | −60 | 70 | 50 |

As shown in FIG. 20, spectrally-narrowed emissions, i.e. the emissions with markedly narrow spectrum width, were observed at particular applied voltage conditions of A and B.

### Fourth Embodiment

(A Light Emitting Transistor According to A Fourth Embodiment)

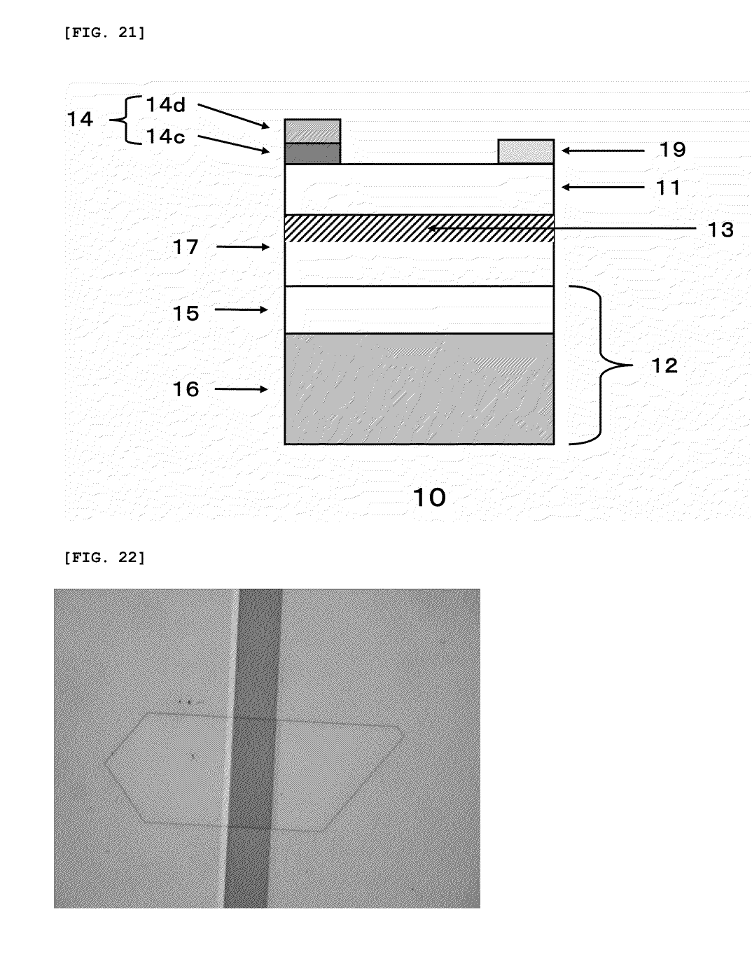

A light emitting transistor according to a fourth embodiment and a fabrication method of the light emitting transistor are illustrated with referring to a schematic structure of the light emitting transistor according to a third embodiment in FIG. 21.

The light emitting transistor according to the fourth embodiment was fabricated in a manner similar to that for the above-mentioned light emitting transistor according to the third embodiment except the following 2 points.

(1) The organic semiconductor crystal 11 was grown directly on the substrate through the solution recrystallization method from BP1T which is shown as chemical formula 9.
(2) No amorphous organic semiconductor film 18 was used.
Fabrication of the Diffraction Grating on the Silicon Substrate with Oxide Layer

The Photoresist layer 17 was formed in a manner similar to that for the light emitting transistor according to the second embodiment. The photoresist layer 17 on the silicon substrate 12 with the dioxide layer was baked in a drying oven to evaporate the unnecessary solvent in the photoresist film first at 65° C. for 10 min, then at 90° C. for 30 min.

The interference exposure of the photoresist layer 17 was carried out in a manner similar to that for the light emitting transistor according to the second embodiment except the energy of the irradiation laser pulse of 475 μJ. To cure the exposure part of the photoresist layer 17, the substrate having the exposed photoresist layer 17 was baked in the drying oven at 65° C. for 10 min, at 90° C. for 30 min, then at 95° C. for 10 min, and was cooled to room temperature in air.

The development of the exposed photoresist layer 17 was carried out in a manner similar to that for the light emitting transistor according to the second embodiment. The silicon substrate 12 including the developed photoresist layer 17 was baked again in the drying oven at 175° C. for 20 min in order to complete the curing reaction for the uncured part of the photoresist layer 17.

### Fabrication of the Slab Crystal of the Organic Semiconductor Material Through the Solution Recrystallization

The organic semiconductor crystal was made through the solution recrystallization.

BP1T was mixed with monochlorobenzene in a glass container with a lid and was crushed by ultrasonic irradiation, and the monochlorobenzene mixture including the excess amount of BP1T was obtained.
The silicon substrate 12 covered with dioxide layer having the photoresist film on which the diffraction grating was formed was clamped with screws on an aluminum plate of 10 mm in width, 100 mm in length and 2 mm in thickness, and the above mentioned silicon substrate 12 was covered with the sheath made of aluminum foil to prevent attaching the BP1T powder in the mixture solution to the substrate.
After the silicon substrate 12 on which the diffraction grating 13 was formed was immersed into the mixture solution, the container was closed with the lid, and the one end of the aluminum plate which was not immersed in the mixture was put outside of the container.
After heating the bottom of the container at 60° C. for 3 days, the BP1T crystal was grown on the diffraction grating so that the crystal was in physical contact with the grating.

JP2008-7377A discloses the crystal growth method through the solution recrystallization.

Electrode Fabrication onto the Crystal Grown on the Diffraction Grating

Electrodes were fabricated on the BP1T crystal grown on the diffraction grating 13 in a manner similar to that for the light emitting transistor according to the third embodiment except the use of a tungsten wire of 30 μm in thickness.

FIG. 22 shows a micrograph of the light emitting transistor 10. The area between the silver electrode 14d and the gold electrode 19 forms the channel. The BP1T crystal 11 is a centrally-positioned hexagon. The longitudinally-extending channel located at the center of the BP1T crystal 11 corresponds to the distance between the electrodes 14d and 19. The thin electrode 14d was recognized at the left side of the channel and the thin electrode 19 was recognized at the right side of the channel.

### Spectrally Narrowed Emissions Under Applying the Sinusoidal-Wave Alternating-Current Voltages to the Gate Contact

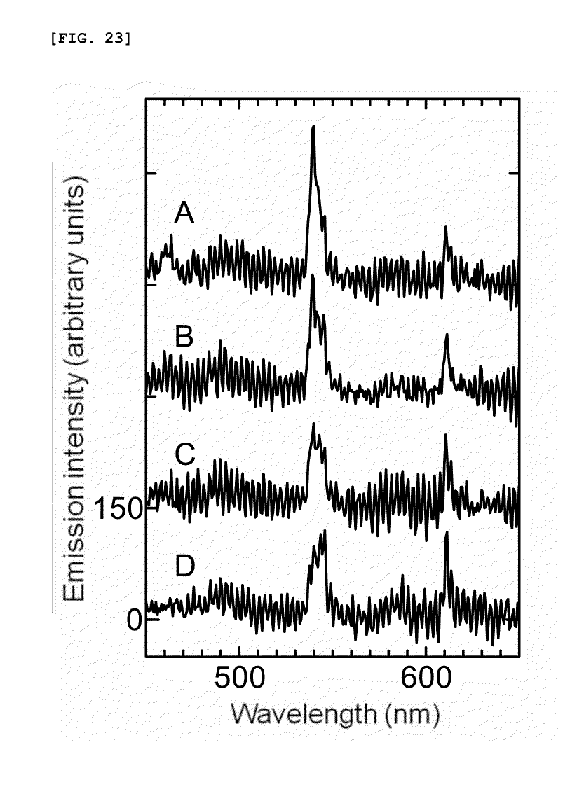

The current-excited emission spectra of the light emitting transistor 10 according to the fourth embodiment were observed in a way similar to that for the first embodiment. FIG. 23 shows the emission spectra of the light emitting transistor 10 according to the fourth embodiment operated under applying as the gate voltage V_{G} the sinusoidal-wave AC voltage. The emission intensities were plotted as a function of wavelength. TABLE 4 summarizes the specific values of the source voltage V_{S}, the drain voltage V_{D}, the AC gate voltage amplitude V_{G}, and the frequency of the AC gate voltage.

TABLE 4

| Symbol | Drain | | Gate voltage | Gate voltage |
|---|---|---|---|---|
| in | voltage | Source | amplitude | frequency |
| FIG. 23 | (V) | voltage (V) | (V) | (kHz) |
| A | 80 | −80 | 90 | 20 |
| B | 70 | −70 | 80 | 20 |
| C | 60 | −60 | 80 | 20 |
| D | 50 | −50 | 80 | 20 |

As shown in FIG. 23, spectrally-narrowed emissions, i.e. the emissions with markedly narrow spectrum width, were observed at particular applied voltage conditions from A to D. The emission peak intensity increased with increase in the magnitude of V_{D}, V_{S}, and V_{G}. In the spectrum A, the peak position and the full-width at half maximum of the dominant narrowed emission were 539.9 nm and 5.44 nm, respectively. The secondary peak was found at 610.6 nm with its full-width at half maximum 2.24 nm.

### Fifth Embodiment

### (A Light Emitting Transistor According to a Fifth Embodiment)

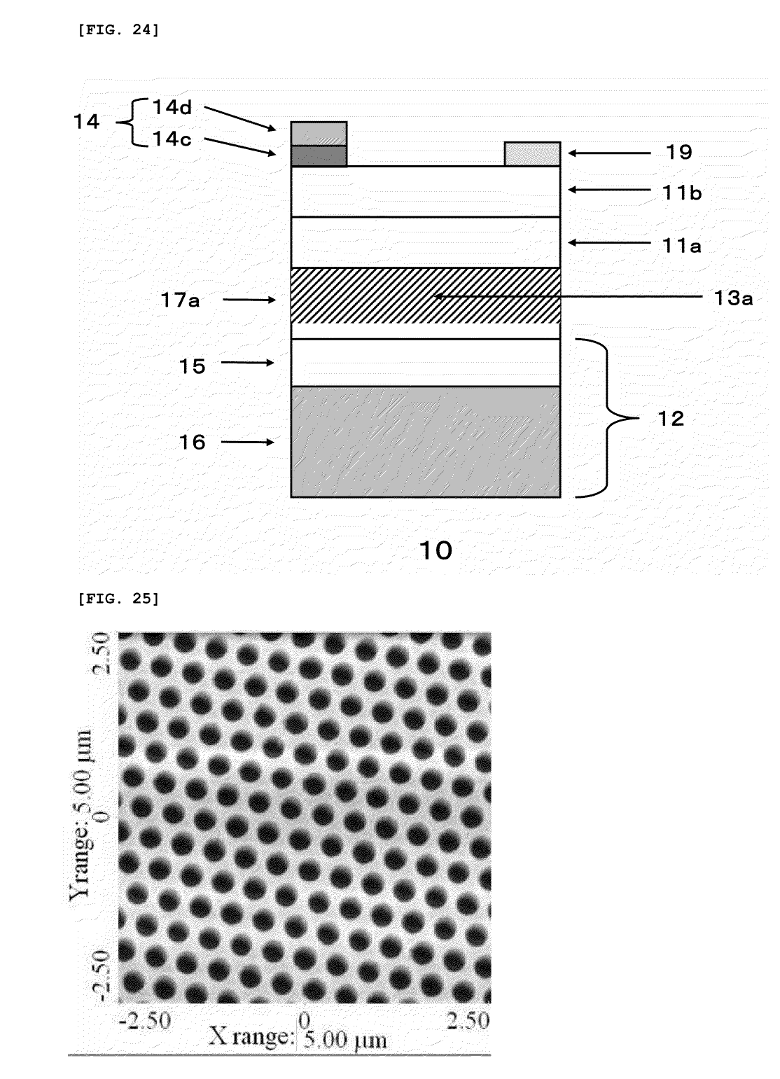

A light emitting transistor according to a fifth embodiment and a fabrication method of the light emitting transistor are illustrated with referring to a schematic structure of the light emitting transistor according to a third embodiment in FIG. 24.

The light emitting transistor according to the fifth embodiment was fabricated in a manner similar to that for the above-mentioned light emitting transistor according to the third embodiment except the following 3 points.
(1) The organic semiconductor crystal 11 was formed by the lamination of an AC5 crystal using AC5 which is shown as chemical formula 22 and an AC5-CF₃ crystal using AC5-CF₃ which is shown as chemical formula 23.
(2) A 2-dimentional periodic structure 13a was formed on the resist layer 17a rather than the diffraction grating 13 on the photoresist layer 17.
(3) No amorphous organic semiconductor film 18 was used.
Fabrication of the 2-Dimentional Periodic Structure on the Device Substrate with the Electrodes

The 2-dimentional periodic structure 13a was fabricated onto the resist layer 17a formed on the silicon substrate 12 with the dioxide layer at SCIVAX Corporation.

The 2-dimentional periodic structure 13a was fabricated by using a nano-imprint lithography technique on the surface of the resist layer 17a separated from the silicon substrate 12. The 2-dimentional periodic structure 13a was fabricated from the resist layer 17 which was first softened by heat and was pressed into a specific mold then was cooled.

FIG. 25 shows the AFM image indicating a part of a two-dimensional view of the 2-dimentional periodic structure 13a formed on the resist layer 17a on the silicon substrate 12 with the oxide layer. The diameter of the air holes was 238 nm, the distance of nearest-neighbor holes (the distance between the centers of nearest-neighbor holes) was 480 nm, and the depth of holes was 225 nm.

Fabrication Of Slab Crystals Of Organic Semiconductor Materials Through The Sublimation Recrystallization Method

The AC5 crystal 11a and AC5-CF₃ crystal 11b were made through the sublimation recrystallization method which is the same as that for the light emitting transistor according to the first embodiment.

In particular, the AC5 crystal 11a was grown for 1 h 5 min at T₁ of 290° C. and T₂ of 250° C. The AC5-CF₃ crystal 11b was grown for 10 h with T₁ of 256° C. and T₂ of 200° C.

Lamination of Slab Crystals of Organic Semiconductor Materials on the 2-Dimentional Periodic Structure

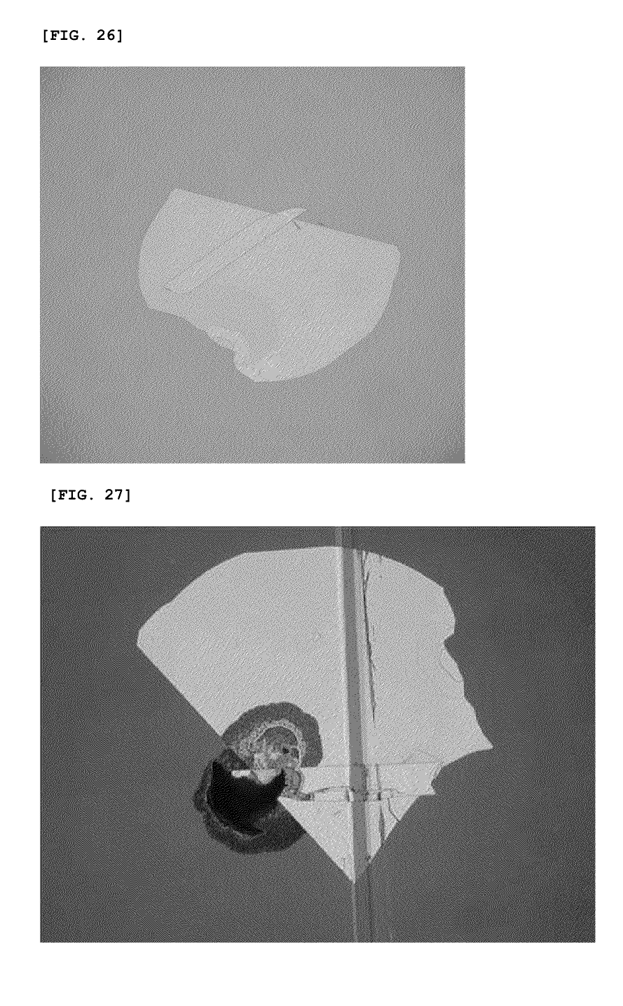

One appropriate organic semiconductor crystal 11b was selected among many AC5 crystals grown through the sublimation recrystallization method, and the AC5 crystal 11a was in physical contact with the 2-dimentional periodic structure 13a by laminating the AC5 crystal 11a on the 2-dimentional periodic structure. In a similar way, one appropriate organic semiconductor crystal 11b was selected among AC5-CF₃ crystals grown through the sublimation recrystallization method, and the AC5-CF₃ crystal 11b was in physical contact with the AC5 crystal 11a by laminating the AC5-CF₃ crystal 11b on the AC5 crystal 11a beforehand laminated on the 2-dimentional periodic structure. FIG. 26 shows a micrograph of the AC5 crystal 11a and AC5-CF₃ crystal 11b arranged on the 2-dimentional periodic structure 13a. This micrograph was taken from the direction perpendicular to the surface of the silicon substrate 12. The AC5 crystal 11a is within the area bounded by a broken line, and AC5-CF₃ is within the long and thin area bounded by a dotted line.

### Electrode Fabrication on the Layered Crystals Laminated on the 2-Dimentional Periodic Structure

Electrodes were fabricated on the lamination structure of the AC5 crystal 11a and the AC5-CF₃ crystal 11b arranged on the 2-dimentional periodic structure 13a in a manner similar to that for the light emitting transistor according to the third embodiment.

FIG. 27 shows a micrograph of the fabricated light emitting transistor 10. The area between the silver electrode 14d and the gold electrode 19 forms the channel. The AC5-CF₃ crystal 11b is transversely-extended in the center position of the micrograph, and AC5 crystal 11a shows a fan-like shape around the center position. The longitudinally-extending channel located at the center of the crystal corresponds to the distance between the electrodes 14d and 19. The thin electrode 14d was recognized at the left side of the channel, and the thin electrode 19 was recognized at the right side of the channel.

### Spectrally Narrowed Emissions Under Applying the Alternating-Current Voltages to the Gate Contact

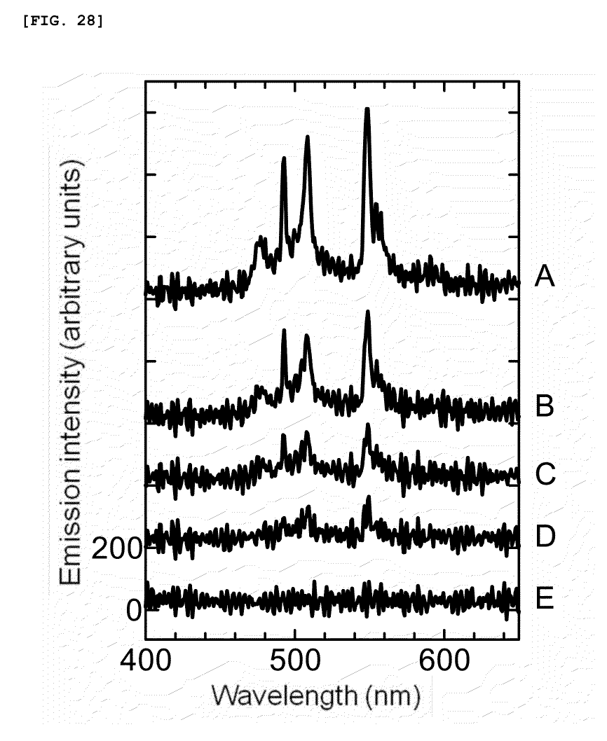

The current-excited emission spectra of the light emitting transistor 10 according to the fifth embodiment were observed in a way similar to that for the first embodiment. FIG. 28 shows the emission spectra of the light emitting transistor 10 according to the fifth embodiment operated under applying as the gate voltage V_{G} the sinusoidal-wave or square-wave AC voltage. The emission intensities were plotted as a function of wavelength. TABLE 5 summarizes the specific values of the source voltage V_{S}, the drain voltage V_{D}, the AC gate voltage amplitude V_{G}, and the frequency of the AC gate voltage, along with the waveform of the AC gate voltage.

TABLE 5

| | | | | Gate | |
|---|---|---|---|---|---|
| Symbol | Drain | Source | Gate voltage | voltage | |
| in | voltage | voltage | amplitude | frequency | |
| FIG. 28 | (V) | (V) | (V) | (kHz) | waveform |
| A | 90 | −90 | 100 | 50 | Square |
| B | 80 | −80 | 90 | 50 | Square |
| C | 70 | −70 | 80 | 50 | Square |
| D | 60 | −60 | 70 | 50 | Square |
| E | 60 | −60 | 70 | 50 | Sinusoidal |

Even if the same source voltage V_{S}, drain voltage V_{D}, AC gate amplitude V_{G}, and frequency of the AC gate voltage were used, spectrally-narrowed emissions were observed not with the sinusoidal-wave (E) but with the square-wave (D) as shown in FIG. 28. The emission peak intensity increased with increase in the magnitude of V_{D, V}_{S}, and V_{G}. In

Spectrum A, the peak positions were located at 453.9, 522.5, 611.8 nm with their full-widths at half maximum of 3.49, 6.68 and 4.36 nm, respectively, from the shorter wavelength.

Thus, the spectrally narrowed emissions, i.e., the emissions with markedly narrow spectrum width, were observed by applying AC voltage to the gate electrode of the light emitting transistor including the organic semiconductor crystal and the diffraction grating or the 2-dimentional periodic structure.

### INDUSTRIAL APPLICABILITY

The present invention provides a light emitting transistor, the process of manufacture, the method of optical amplification or optical linewidth reduction. The present invention is especially useful to obtain light emission with distinct spectrum peak by using electric energy of a low domestic voltage.

### Related Patent Application

This patent application claims priority to and benefit of Japanese Patent Application No. 2010-028600 filled on Feb. 12, 2010 under Article 4 of the Paris Convention. The content of this basic application is incorporated herein by reference.

1-4. (canceled)

5. A light emitting transistor comprising:
a light emitting layer made from an organic semiconductor material;
a source electrode electrically connected with the light emitting layer;
a drain electrode electrically connected with the light emitting layer;
a gate electrode connected with the light emitting layer through an insulation layer; and
a periodic structure contacted with the light emitting layer or the insulation layer contacted with the light emitting layer, wherein
an AC voltage is applied to the gate electrode, wherein
the periodic structure is formed in the light emitting layer or the insulation layer, which layer at least partly overlaps with an area sandwiched between a pair of two line segments which are formed by edge lines of both the source electrode and the drain electrode in contact with a channel or with an area sandwiched between two straight lines formed by extending the pair of the two line segments, wherein
a light is emitted from the light emitting layer between the source electrode and the drain electrode; intensity of the light is amplified and linewidth of spectrum of the light is narrowed when the light passes in the periodic structure along continuing direction of the periodic structure arranged in a direction parallel to the principal plane in the light emitting layer; and then the light radiates in a direction parallel to the main surface of the light emitting layer.

6. The light emitting transistor according to claim 5, wherein the light emitting layer includes a tabular crystal of the organic semiconductor material.

7. The light emitting transistor according to claim 5, wherein the periodic structure is at least one kind selected from a group consisting of a one-dimensional diffraction grating, a two-dimensional diffraction grating, a photonic crystal and a multilayer film.

8. The light emitting transistor according to claim 6, wherein the periodic structure is at least one kind selected from a group consisting of a one-dimensional diffraction grating, a two-dimensional diffraction grating, a photonic crystal and a multilayer film.
